(19) United States
(12) Patent Application Publication
(10) Pub. No.: US 2004/0261718 A1
(43) Pub. Date: Dec. 30, 2004

(54) Plasma source coil for generating plasma and plasma chamber using the same

(76) Inventors: Nam Hun Kim, Suwon-city (KR); Joon Hun Kim, Seoul (KR)

Correspondence Address: LADAS & PARRY LLP, 224 SOUTH MICHIGAN AVENUE, SUITE 1200, CHICAGO, IL, 60604, US

(21) Appl. No.: 10/872,873

(22) Filed: Jun. 21, 2004

(30) Foreign Application Priority Data
Jun. 26, 2003 (KR) 2003-42111
Jul. 1, 2003 (KR) 2003-44396
Jul. 7, 2003 (KR) 2003-45642
Jul. 16, 2003 (KR) 2003-48645
Aug. 26, 2003 (KR) 2003-59138

(51) Int. Cl. C23C 16/00

(52) U.S. Cl. 118/723 AN; 118/723 I

(57) ABSTRACT

Provided are a plasma source coil for generating plasma and a plasma chamber using the same. The plasma source coil receives power from a power supplier to generate uniformly plasma in a predetermined reaction space. The plasma source coil includes m (here, m≧2, and m is an integer) unit coils, each of which has a number n of turns (here, n is a positive real number). The unit coils extend from a coil bushing, which is located in the center of the plasma source coil and has a predetermined radius, and are arranged in a spiral shape around the coil bushing.

This application claims the priorities of Korean Patent Applications No. 2003-42111, filed on Jun. 26, 2003, No. 2003-44396, filed on Jul. 1, 2003, No. 2003-45642, filed on Jul. 7, 2003, No. 2003-48645, filed on Jul. 16, 2003 and No. 2003-59138, filed on Aug. 26, 2003 in the Korean Intellectual Property Office, the contents of which are incorporated herein in their entirety by reference.

### BACKGROUND OF THE INVENTION

1. Field of the Invention

The present invention relates to a semiconductor manufacturing apparatus, and more particularly, to a plasma source coil for generating plasma and a plasma chamber using the same.

2. Description of the Related Art

Ultra-Large Scale Integration (ULSI) technology has remarkably developed during the past twenty years. This has been possible because semiconductor manufacturing techniques, which had reached technical limits, could be supported by semiconductor manufacturing apparatuses. A plasma chamber, as one of these semiconductor manufacturing apparatuses, is widely used in various applications covering not only an etch process but also a deposition process.

Plasma chambers are used to generate plasma and to perform etch processes, deposition processes, and the likes using the generated plasma. The plasma chambers employ various plasma generating sources, which can be categorized into an electron cyclotron resonance (ECR) plasma source, a helicon-wave excited plasma (HWEP) source, a capacitively coupled plasma (CCP) source, or an inductively coupled plasma (ICP) source. The ICP source supplies radio frequency (RF) power to an induction coil to generate a magnetic field. An electric field induced by the magnetic field stores electrons in the center of a plasma chamber to generate high-density plasma even at low pressure. The ICP source is broadly used since it is structurally simpler than the ECR plasma source or the HWEP source and facilitates the generation of large-area plasma.

In a plasma chamber using the ICP source, a large RF current flows through a coil constituting an inductor of a resonance circuit. Here, the amount of RF current significantly affects the distribution of generated plasma in the plasma chamber. Generally, it is well known that a coil constituting an inductor has its own resistance. Hence, as a current flows through the coil, energy is dissipated due to the coil's resistance and converted to heat. As a result, the amount of current flowing through the coil decreases. If the amount of current flowing through the coil is non-uniform, the plasma generated in the chamber may be non-uniformly distributed.

FIG. 1 is a graph showing the distribution of the density nᵢ of plasma and the rate ΔCD of change in critical dimension (CD) in a conventional semiconductor manufacturing plasma apparatus with a plasma source coil. Hereinafter, a difference between a CD expected before a process is performed and a CD obtained after the process is performed will be referred to as a rate ΔCD of change in CD.

In FIG. 1, as can be seen from curve 12 showing the density nᵢ of plasma, while the center of a wafer has the greatest density nᵢ of plasma, an edge of the wafer has the smallest density nᵢ of plasma. As can be seen from a curve 14 showing the rate ΔCD of change in CD, similarly to the density nᵢ of plasma, while the center of the wafer has the greatest rate ΔCD of change in CD, the edge of the wafer has the smallest rate ΔCD of change in CD.

Conventionally, many attempts have been made to solve the problem of non-uniform density of plasma by using improved processes. However, various manufacturing processes, such as a lithography process, are bound by technical limits and fail to obtain a uniform density of plasma. Therefore, developing a semiconductor manufacturing plasma apparatus capable of generating uniform plasma on its own is required.

Even if uniform plasma can be generated, the rate ΔCD of change in CD in the center of the wafer may still differ from that in the edge of the wafer during, for example, an etch process using a plasma chamber. During the etch process, chemical reactions occur, thus generating byproducts. There is a difference in a diffusing speed of removing the byproducts between the center of the wafer and the edge thereof. That is, whereas the diffusing speed of removing byproducts is relatively low in the center of the wafer, the diffusing speed of removing the byproducts is relatively high in the edge of the wafer. To solve this problem, the etch rate should be reduced in the edge of the wafer. Also, a plasma source coil having various structures capable of controlling the density of plasma is required.

### SUMMARY OF THE INVENTION

According to an aspect of the present invention, there is provided . . . claims 1˜62.

### BRIEF DESCRIPTION OF THE DRAWINGS

The above and other features and advantages of the present invention will become more apparent by describing in detail exemplary embodiments thereof with reference to the attached drawings in which:

FIG. 1 is a graph showing the distribution of the density nᵢ of plasma and the rate ΔCD of change in CD in a conventional semiconductor manufacturing plasma apparatus with a plasma source coil;

FIG. 2 is a plan view of a plasma source coil according to an embodiment of the present invention;

FIG. 3 is a cross-sectional view of a plasma chamber including the plasma source coil of FIG. 2;

FIG. 4A is a plan view of a plasma source coil according to another embodiment of the present invention;

FIG. 4B is a graph showing a variation of an interval between portions of a unit coil according to a radial distance from the center of a coil in the plasma source coil of FIG. 4A;

FIG. 5A is a plan view of a plasma source coil according to another embodiment of the present invention;

FIG. 5B is a graph showing a variation of a sectional area of a coil according to a radial distance from the center of the coil in the plasma source coil of FIG. 5A;

FIG. 5C is a graph showing a variation of an interval between portions of a unit coil according to the radial distance from the center of the coil in the plasma source coil of FIG. 5A;

FIG. 6A is a plan view of a plasma source-coil according to another embodiment of the present invention;

FIG. 6B is a graph showing a variation of a sectional area of a coil according to a radial distance from the center of the coil in the plasma source coil of FIG. 6A;

FIG. 6C is a graph showing a variation of an interval between portions of a unit coil according to the radial distance from the center of the coil in the plasma source coil of FIG. 6A;

FIGS. 7A through 7K are plan views illustrating shapes of coil bushings of the plasma source coils according to the present invention;

FIGS. 8A through 8E show various sectional shapes of unit coils of plasma source coils of the present invention;

FIGS. 9 and 10 are plan views of plasma source coils according to another embodiment of the present invention;

FIG. 11 is a cross-sectional view of a dome of the plasma chamber of FIG. 3;

FIGS. 12 through 45 are cross-sectional views of domes and plasma source coils of plasma chambers according to embodiments of the present invention;

FIG. 46 shows a plasma source coil according to another embodiment of the present invention;

FIG. 47 is a cross-sectional view of a plasma chamber using the plasma source coil of FIG. 46;

FIG. 48 is a plan view of a plasma source coil according to another embodiment of the present invention;

FIG. 49 is a plan view of a plasma source coil according to another embodiment of the present invention;

FIG. 50 is a cross-sectional view of a plasma chamber using the plasma source coil of FIG. 49;

FIG. 51A is a plan view of a plasma source coil according to another embodiment of the present invention;

FIG. 51B is a cross-sectional view taken along line IB-IB′ of FIG. 51A;

FIGS. 52 through 67 show plasma source coils according to another embodiments of the present, invention;

FIG. 68 is a cross-sectional view of a plasma chamber according to another embodiment of the present invention;

FIG. 69 shows an example of a plasma source coil of the plasma chamber of FIG. 68;

FIG. 70 is a cross-sectional view of a plasma chamber according to another embodiment of the present invention;

FIG. 71 shows an example of a plasma source coil of the plasma chamber of FIG. 70;

FIG. 72 is a cross-sectional view of a plasma chamber according to another embodiment of the present invention;

FIG. 73 shows an example of a plasma source coil of the plasma chamber of FIG. 72;

FIG. 74 is a cross-sectional view of a plasma chamber according to another embodiment of the present invention; and

FIG. 75 shows an example of a plasma source coil of the plasma chamber of FIG. 74.

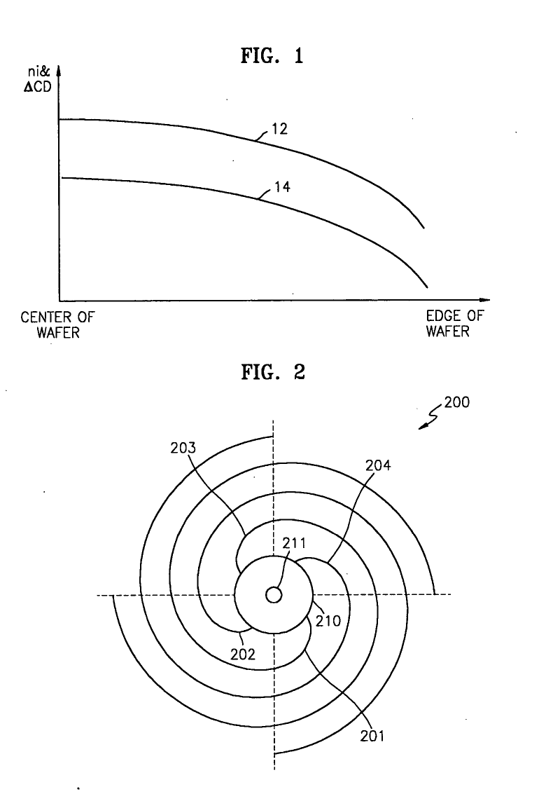

### DETAILED DESCRIPTION OF THE INVENTION

Referring to FIG. 2, a plasma source coil 200 is made up of a coil bushing 210 located in the center thereof and a plurality of unit coils 201, 202, 203, and 204, which spirally coil around the coil bushing 210. Although four unit coils 201, 202, 203, and 204 are exemplarily used in the present embodiment, the present invention is not limited to the above-description. The plasma source coil 200 can include m coils (here, m≧2, and m is an integer). Each of the unit coils 201, 202, 203, and 204 has a number n of turns (here, n is a positive real number). The number of turns of each of the unit coils 201, 202, 203, and 204 may not be an integer.

The coil bushing 210 is formed of the same material as the plurality of unit coils 201, 202, 203, and 204. For example, if the unit coils 201, 202, 203, and 204 are formed of copper, the coil bushing 210 can also be formed of copper. The coil bushing 210 may be formed of a different material from the unit coils 201, 202, 203, and 204 according to circumstances, but should be formed of a conductive material anyhow. A support bar 211 is located in the center of the coil bushing 210 and protrudes perpendicular to a top surface of the coil bushing 210. The support bar 211 is also formed of a conductive material, for example, copper.

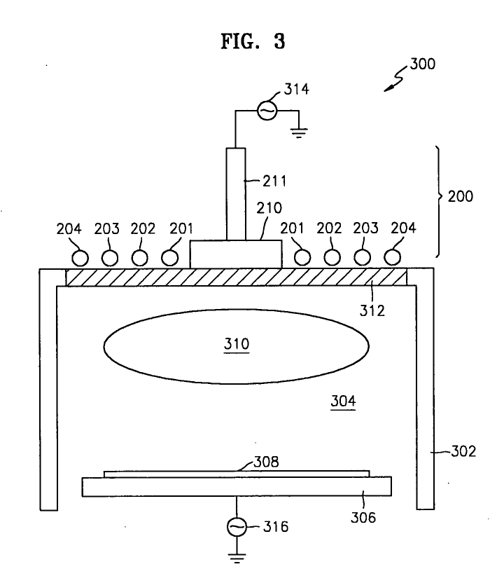

Referring to FIG. 3, in a plasma chamber 300 including the plasma source coil 200, a proper size of inner space 304 is defined by outer walls 302 and a dome 312. Although the inner space 304 of the plasma chamber 300 is externally open in the drawing for simplicity, the inner space 304 is externally shut for practical use to maintain vacuum in the plasma chamber 300. A wafer support 306 is located at a lower portion of the inner space 304 to support semiconductor wafers 308 having certain patterns. An RF power supplier 316 is connected to the wafer support 306.

The plasma source coil 200 for generating plasma is located on an outer surface of the dome 312. The plane structure of the plasma source coil 200 was described with reference to FIG. 2. That is, a coil bushing 210 is located in the center of a top surface of the dome 312, and unit coils 201, 202, 203, and 204 spirally coil around the coil bushing 211. Although not shown in FIG. 3, one terminal of each of the unit coils 201, 202, 203, and 204 is connected to the coil bushing 210, and the other terminal thereof is grounded. A support bar 211 is located in the center of the coil bushing 210 and protrudes perpendicular to the surface of the coil bushing 210. An RF power supplier 314 is connected to the support bar 211. Thus, the RF power supplier 314 supplies RF power to the unit coils 201, 202, 203, and 204 via the support bar 211 and the coil bushing 210.

In this plasma chamber 300, the unit coils 201, 202, 203, and 204 receive RF power from the RF power supplier 314 to generate an electric field. The electric field passes through the dome 312 and is induced in the inner space 304 of the plasma chamber 300. The electric field induced in the inner space 304 produces gas discharge in the inner space 304 of the plasma chamber 300, thus generating plasma. The resultant neutral radicals react on charged ions to thereby process the surface of a semiconductor wafer 308. In conventional plasma chambers, the density of plasma produced in an inner space has the greatest value in the center of a wafer and has the smallest value in an edge of the wafer. Unlike the conventional plasma chambers having a non-uniform density of plasma, in the plasma chamber 300 of the present invention, the density of plasma is properly reduced in the center of the wafer 308 due to the coil bushing 210. Thus, the density of plasma becomes uniform inside the entire plasma chamber 300.

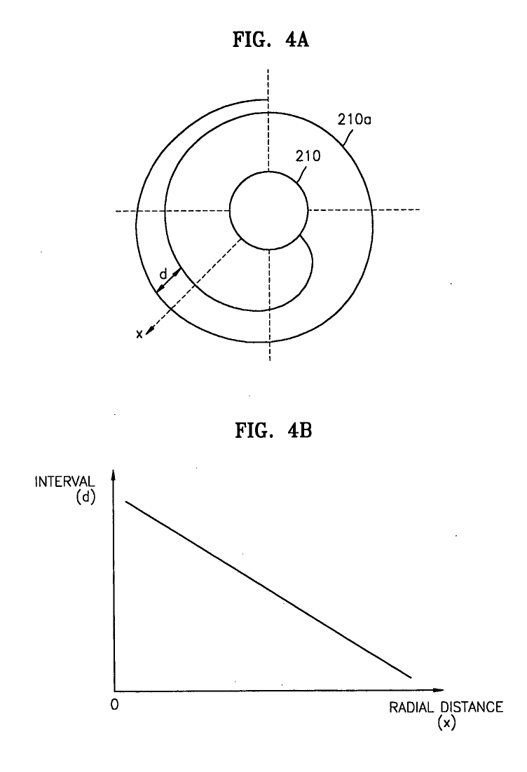

FIG. 4A is a plan view of a plasma source coil capable of generating plasma uniformly, according to another embodiment, which exemplarily illustrates only a unit coil. FIG. 4B is a graph showing a variation of an interval between portions of a unit coil according to a radial distance from the center of the coil of FIG. 4A.

As shown in FIGS. 4A and 4B, a unit coil 201a diverges from a coil bushing 210 located in the center of the entire coil and spirally coils around the coil bushing 210. The unit coil 201a is structured such that as the radial distance from the center of the coil bushing 210 increases, e.g., in an x direction, an interval d between portions of the unit coil 201a in the x direction decreases. That is, as the radial distance decreases, the interval d increases. Inversely, as the radial distance increases, the interval d decreases. Thus, as the coil 201a extends farther from the center of the coil bushing 210 in a radial direction, an interval between currents flowing through the coil 201a becomes narrower. Hence, the amount of current per area increases. This makes the density of plasma increase in an edge of a wafer corresponding to a portion of the coil 201a, which is farthest from the center of the coil bushing 210. Further, since the density of plasma decreases in the center of the wafer due to the coil bushing 210, the entire wafer can have a uniform density of plasma irrespective of positions. Although only one unit coil 201a is shown in FIG. 4A, it is obvious that other unit coils of the same structure as the unit coil 201a can be further included.

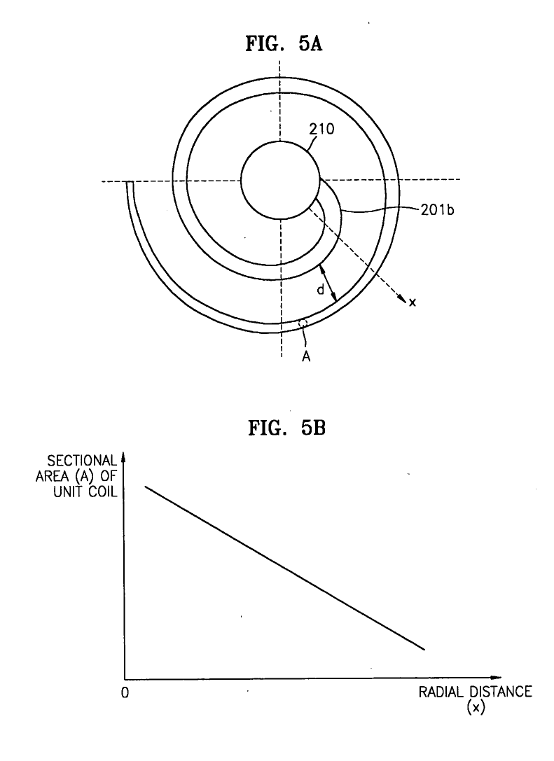

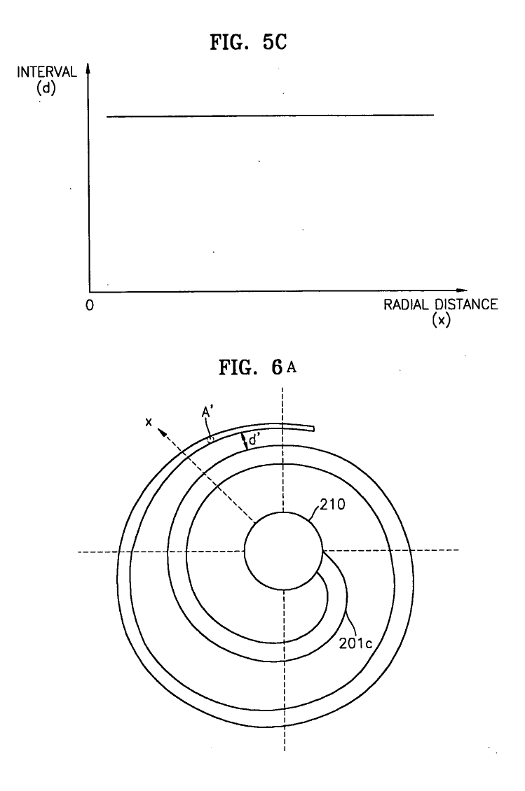

FIG. 5A is a plan view of a plasma source coil capable of generating plasma uniformly, according to another embodiment of the present invention, which exemplarily illustrates only one unit coil. FIG. 5B is a graph showing a variation of a sectional area of the unit coil according to a radial distance from the center of the coil of FIG. 5A, and FIG. 5C is a graph showing a variation of an interval between portions of the unit coil according to the radial distance from the center of the coil in the plasma source coil of FIG. 5A.

Referring to FIGS. 5A, 5B, and 5C, a unit coil 201b diverges from a coil bushing 210 located in the center of the plasma source coil and spirally coils around the coil bushing 210. The unit coil 201b is structured such that as the radial distance from the center of the coil bushing 210 increases, e.g., in an x direction, the sectional area A of the unit coil 201b decreases, but the interval d between portions of the unit coil 201b is held constant. That is, as the radial distance decreases, the sectional area A increases. Inversely, as the radial distance increases, the sectional area A decreases. Thus, even though the amount of current is constant irrespective of the radial distance, as the coil 201b extends farther from the center of the coil bushing 210 in a radial direction, the density of current flowing through the unit coil 201b increases. This makes the density of plasma increase in an edge of a wafer corresponding to a portion of the coil 201b, which is farthest from the center of the coil bushing 210. Further, since the density of plasma decreases in the center of the wafer due to the coil bushing 210, the entire wafer can have a uniform density of plasma irrespective of positions. Although only one unit coil 201b is shown in FIG. 5A, it is obvious that other unit coils of the same structure as the unit coil 201b can be further included.

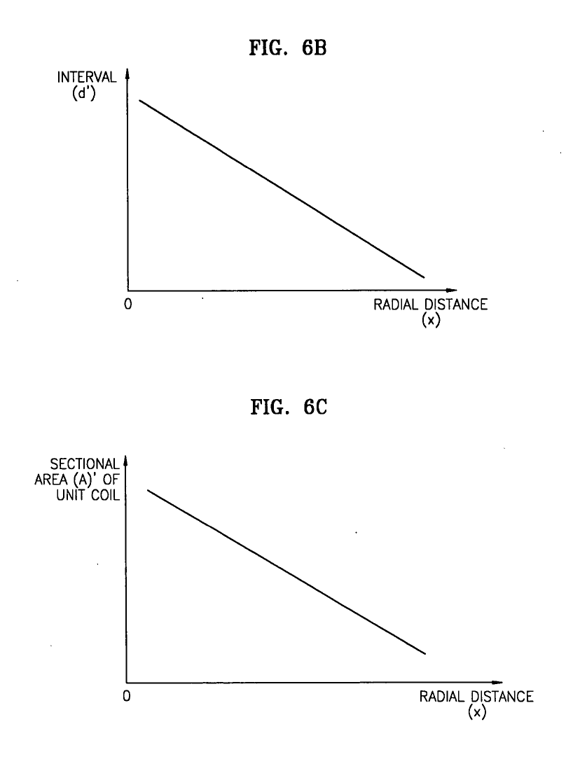

FIG. 6A is a plan view of a plasma source coil capable of generating plasma uniformly, according to another embodiment of the present invention, which exemplarily illustrates only one unit coil. FIG. 6B is a graph showing a variation of a sectional area of the unit coil according to a radial distance from the center of the coil of FIG. 6A, and FIG. 6C is a graph showing a variation of an interval between portions of the unit coil according to the radial distance from the center of the coil of FIG. 6A.

Referring to FIGS. 6A, 6B, and 6C, a unit coil 201c diverges from a coil bushing 210 located in the center of the entire coil and spirally coils around the coil bushing 210. The unit coil 201c is structured such that as the radial distance from the center of the coil bushing 210 increases, e.g., in an x direction, both the interval d′ between portions of the unit coil 201c and the sectional area A′ of the unit coil 201c decrease. That is, this plasma source coil is obtained by combining the plasma source coils shown in FIGS. 4A and 5A. Hence, as the coil 201c extends farther from the center of the coil bushing 210 in a radial direction, the density of current flowing through the unit coil 201c increases most effectively. This makes the density of plasma increase at the highest rate in an edge of a wafer corresponding to a portion of the coil 201c, which is farthest from the center of the coil bushing 210. Further, since the density of plasma decreases in the center of the wafer due to the coil bushing 210, the entire wafer can have a uniform density of plasma irrespective of positions. Although only one unit coil 201c is shown in FIG. 6A, it is obvious that other unit coils of the same structure as the unit coil 201c can be further included.

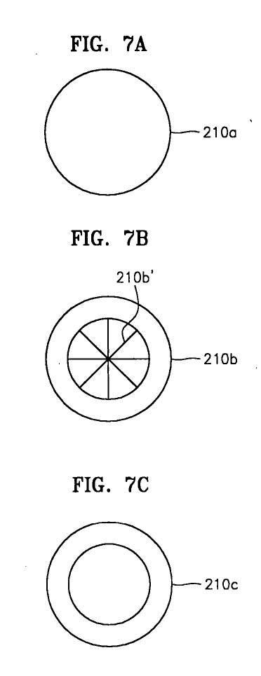

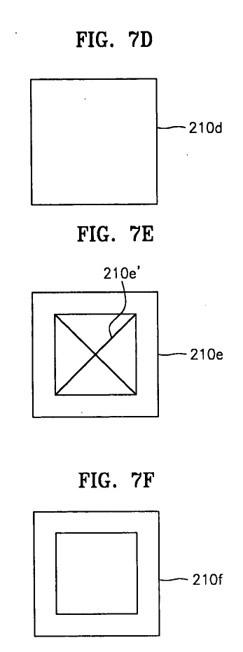

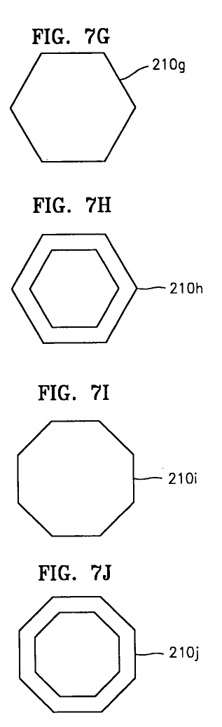

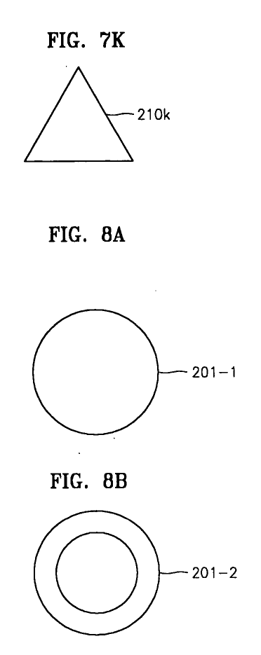

FIGS. 7A through 7K are plan views illustrating shapes of coil bushings of the plasma source coils according to the present invention.

Referring to FIG. 7A, a coil bushing 210a can have a simple circular shape. In FIG. 7A, the sectional area of the coil bushing 210a can vary, thereby affecting the distribution of the density of plasma inside a plasma chamber, particularly, in the center of a wafer. The radius of the coil bushing 210a, which determines the sectional area of the coil bushing 210a, also affects the distribution of the density of plasma. Referring to FIG. 7B, a coil bushing 210b can have a circular donut shape so as to define a vacant central space. Branches 210b′ are located in the vacant central space. Hereinafter, this structure in which the branches 210b′ are located in the certain space of the coil bushing 210b as shown in FIG. 7B will be referred to as a mesh structure. Referring to FIG. 7C, a coil bushing 210c can have a circular donut shape so as to define a vacant central space, but does not include branches in the vacant central space unlike the coil bushing 210b of FIG. 7B. The coil bushing 210c of FIG. 7C having a completely vacant central space has a greater effect of reducing the density of plasma in the center of a wafer than the coil bushing 210b of FIG. 7B having the branches 210b′.

Referring to FIG. 7D, a coil bushing 210d can have a simple square shape. In FIG. 7D, the sectional area of the coil bushing 210d can vary, thereby affecting the distribution of the density of plasma in the center of a wafer. Thus, the length and/or the width of the coil bushing 210d, which determine the sectional area of the coil bushing 210d, also affect the distribution of the density of plasma. Referring to FIG. 7E, a coil bushing 210e can have a square donut shape so as to define a vacant central space. The coil bushing 210e has a mesh structure in which branches 210e′ are located in a vacant central space. Referring to FIG. 7F, a coil bushing 210f can have a square donut shape so as to define a vacant central space, but does not include branches in a vacant central space unlike the coil bushing 210e of FIG. 7E. The coil bushing 210f of FIG. 7F having a completely vacant central space has a greater effect of reducing the density of plasma in the center of a wafer than the coil bushing 210e of FIG. 7E having the branches 210e′.

Referring to FIGS. 7G through 7K, coil bushings have a polygonal shape. As shown in FIGS. 7G and 7I, coil bushings 210g and 210i have a hexagonal shape and an octagonal shape, respectively. As shown in FIGS. 7H and 7J, coil bushings 210h and 210j have a hexagonal donut shape and an octagonal donut shape, respectively. Also, as shown in FIG. 7K, a coil bushing 210k has a triangular shape. As described above, the coil bushings 210h and 210j of FIGS. 7H and 7J, each of which has a vacant central space, can reduce the density of plasma in the center of a wafer more effectively than the coil bushings 210g and 210i of FIGS. 7G and 7I. Of course, a coil bushing of the present invention can have various shapes other than the shapes shown in FIGS. 7A through 7K.

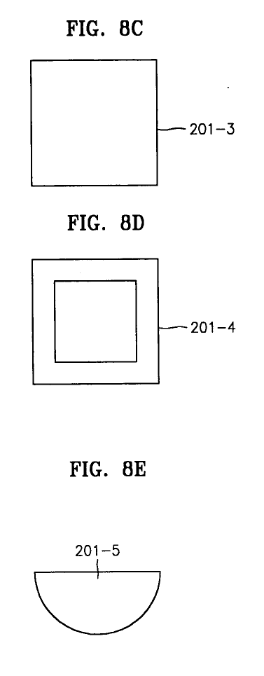

FIGS. 8A through 8E show various sectional shapes of unit coils of plasma source coils of the present invention.

As shown in FIGS. 8A through 8E, the unit coils of the present invention can have various sectional shapes. For example, there are a unit coil 201-1 having a circular sectional shape, a unit coil 201-2 having a circular donut sectional shape, a unit coil 201-3 having a square sectional shape, a unit coil 201-4 having a square donut sectional shape, and a unit coil 201-5 having a semicircular shape. Of course, the unit coil of the present invention can have other various sectional shapes.

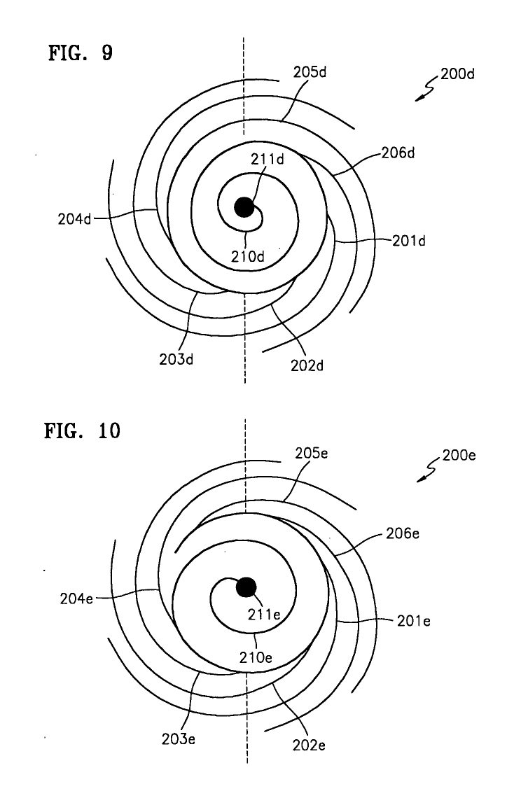

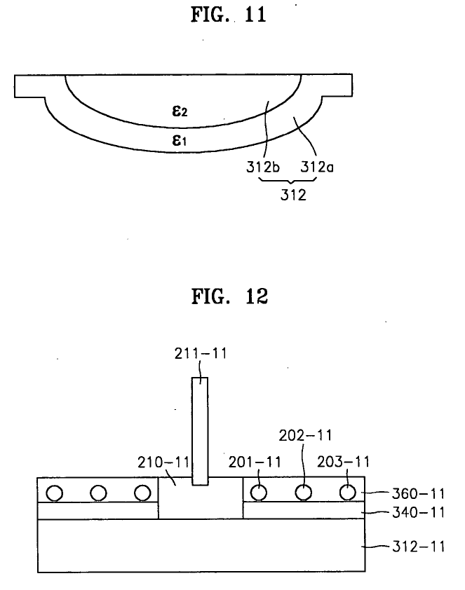

FIGS. 9 and 10 are plan views of plasma source coils capable of generating plasma uniformly, according to another embodiment of the present invention.

Referring to FIG. 9, a plasma source coil 200d is made up of a unit coil 210d located in the center of the plasma source coil 200d and a plurality of unit coils 201d, 202d, 203d, 204d, 205d, and 206d, which spirally coil around the unit coil 210d. Referring to FIG. 10, a plasma source coil 200e is made up of a unit coil 210e located in the center of the plasma source coil 200e and a plurality of unit coils 201e, 202e, 203e, 204e, 205e, and 206e, which spirally coil around the unit coil 210e. The plasma source coils 200d and 200e are obtained by replacing the coil bushing 210 of FIG. 2 by the unit coils 210d and 210e, respectively. As shown in FIG. 9, the unit coil 210d may coil counterclockwise. Alternatively, as shown in FIG. 10, the unit coil 210e may coil clockwise. In any case, the plurality of unit coils 201d, 202d, 203d, 204d, 205d, and 206d or 201e, 202e, 203e, 204e, 205e, and 206e extend from the outermost portions of the unit coil 210d or 210e and coil around the unit coil 210d or 210e. The present invention is not limited to the above-described number (i.e., 6) of unit coils that coil around the central unit coil 210d or 210e.

FIG. 11 is a cross-sectional view of the dome of the plasma chamber of FIG. 3.

Referring to FIG. 11, the dome 312 of the plasma chamber (300 of FIG. 3) according to the present invention is comprised of two material layers having different dielectric constants ε1 and ε2, respectively. More specifically, the dome 312 has a lower dome 312a and an upper dome 312b. A bottom of the lower dome 312a faces the semiconductor wafer (308 of FIG. 3) and is exposed to the inner space (304 of FIG. 3). A top surface of the upper dome 312b is exposed out of the plasma chamber 300. A top surface of the lower dome 312a is in contact with a bottom of the upper dome 312b. The top surface and bottom of the lower dome 312a and the bottom of the upper dome 312b protrude toward the inner space 304 of the plasma chamber 300. The lower dome 312a is formed of a material having a predetermined first dielectric constant ε1, for example, alumina (Al₂O₃) having a dielectric constant of 9.3 to 9.8. The upper dome 312b is formed of a material having a predetermined second dielectric constant ε2 that is smaller than the first dielectric constant ε1, for example, ceramic. It is obvious that the plasma chamber 300 having the dome 312 of FIG. 11 can have one of the above-described plasma source coils of the present invention.

FIGS. 12 through 45 are cross-sectional views of domes and plasma source coils of plasma chambers according to embodiments of the present invention.

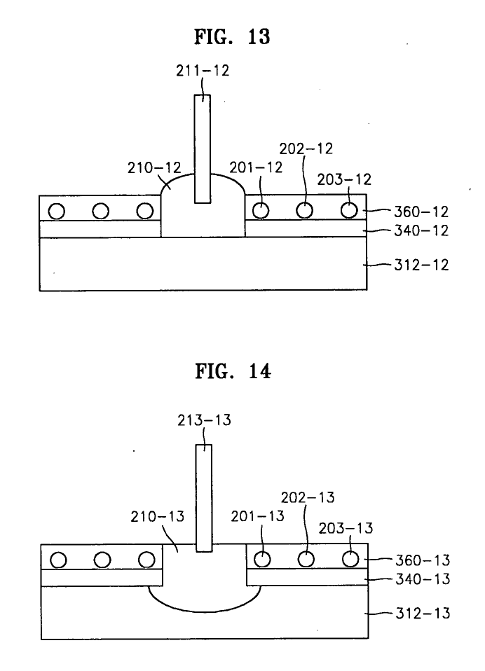

Referring to FIG. 12, a coil bushing 210-11 and a planarizer 340-11 are disposed on a top surface of a dome 312-11, which is the reverse side of a bottom of the dome 312-11 that faces an inner space of a plasma chamber. The planarizer 340-11 is typically formed of plastic or ceramic or may be air that fills a vacant space, according to circumstances. The coil bushing 210-11 is located in the center of the dome 312-11, and the planarizer 340-11 is disposed to surround the coil bushing 210-11. The dome 312-11 is formed of alumina. A support bar 211-11 is located in the center of a top surface of the coil bushing 210-11. The dome 312-11 has planar bottom and top surfaces, and the coil bushing 210-11 also has planar bottom and top surfaces. A heat emissive layer 360-11 is disposed on the planarizer 340-11, and a plurality of unit coils 201-11, 202-11, and 203-11 are located inside the heat emissive layer 340-11. Of course, the plasma source coils that are described with reference to FIGS. 2, 4A, 5A, 6A, 9, and 10 can be applied not only to the plasma source coil of FIG. 12, which is made up of the plurality of unit coils 201-11, 202-11, and 203-11, the coil bushing 210-11, and the support bar 211-11, but also to plasma source coils that will be described hereinafter with reference to FIGS. 13 through 46.

Referring to FIG. 13, a coil bushing 210-12 is located in the center of a top surface of a dome 312-12. While a bottom of the coil bushing 210-12 is planar, a top surface thereof has a convex form. A support bar 211-12 is located in the center of the convex top surface of the coil bushing 210-12. Unlike the coil bushing 210-12, the dome 312-12 has planar bottom and top surfaces. A planarizer 340-12 and a heat emissive layer 360-12 are sequentially disposed on the top surface of the dome 312-12 where the coil bushing 210-12 is not located, so as to surround the coil bushing 210-12. A plurality of unit coils 201-12, 202-12, and 203-12 are located inside the heat emissive layer 360-12.

Referring to FIG. 14, a coil bushing 210-13 is located in the center of a top surface of a dome 312-13. While a bottom of the coil bushing 210-13 has a concave form, a top surface thereof is planar. A support bar 211-13 is located in the center of the planar top surface of the coil bushing 210-13. The dome 312-13 has a planar bottom, but has a concave portion of the top surface, which contacts the bottom of the coil bushing 210-13. A planarizer 340-13 and a heat emissive layer 360-13 are sequentially disposed to surround the coil bushing 210-13. A plurality of unit coils 201-13, 202-13, and 203-13 are located inside the heat emissive layer 360-13.

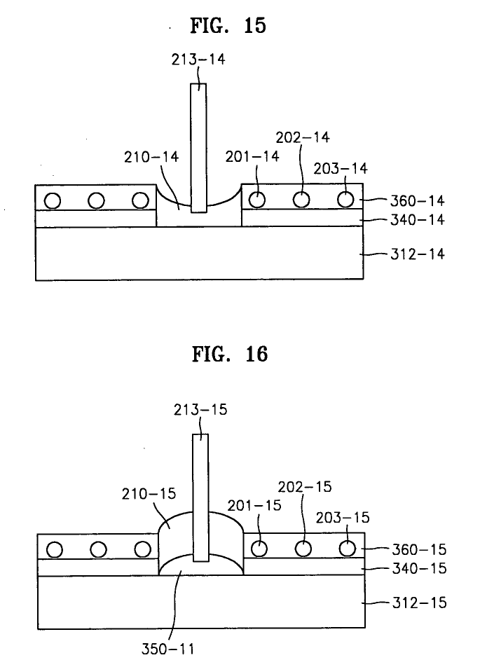

Referring to FIG. 15, a coil bushing 210-14 is located in the center of a top surface of a dome 312-14. While a bottom of the coil bushing 210-14 is planar, a top surface thereof has a concave form. A support bar 211-14 is located in the center of the concave top surface of the coil bushing 210-14. Unlike the coil bushing 210-14, the dome 312-14 has planar bottom and top surfaces. A planarizer 340-14 and a heat emissive layer 360-14 are sequentially disposed to surround the coil bushing 210-14. A plurality of Unit coils 201-14, 202-14, and 203-14 are located inside the heat emissive layer 360-14.

Referring to FIG. 16, a dielectric layer 350-11 and a coil bushing 210-15 are sequentially disposed in the center of a top surface of a dome 312-15. The dielectric layer 350-11 may be formed of plastic or ceramic or may be air that fills a vacant space, according to circumstances. The dome 312-15 has planar bottom and top surfaces, and the dielectric layer 350-11 has a planar bottom surface. However, a top surface of the dielectric layer 350-11 has a convex form. Similarly, a top surface of the coil bushing 210-15 has a convex form. Thus, a bottom of the coil bushing 210-15, which contacts the top surface of the dielectric layer 350-11, also has a convex form. A support bar 211-15 is located in the center of the convex top surface of the coil bushing 210-15. A planarizer 340-15 and a heat emissive layer 360-15 are sequentially disposed to surround the coil bushing 210-15. A plurality of unit coils 201-15, 202-15, and 203-15 are located inside the heat emissive layer 360-15.

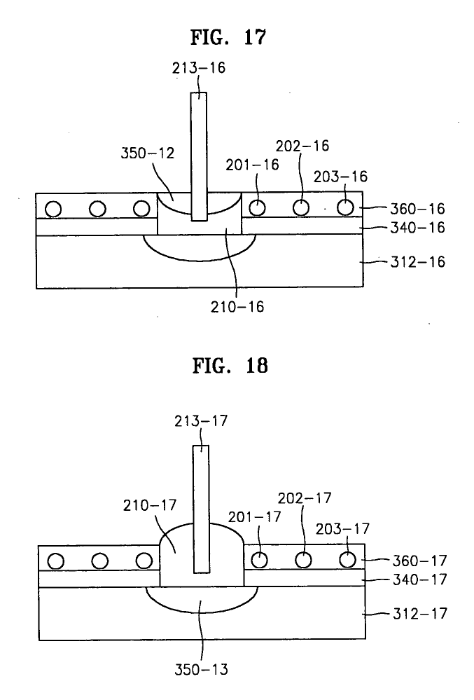

Referring to FIG. 17, a ceramic layer 360-11 is inserted into a central portion of a top surface of a dome 312-16, and a coil bushing 210-16 and a dielectric layer 350-12 are sequentially disposed on the ceramic layer 360-11. The ceramic layer 360-11 may be replaced by another insulating material layer. The dielectric layer 350-12 may be formed of plastic or ceramic or may be air that fills a vacant space, according to circumstances. The dome 312-16 has a planar bottom surface, and the ceramic layer 360-11 has a planar top surface. A top surface of the coil bushing 210-16 located on the ceramic layer 360-11 has a concave form. A top surface of the dielectric layer 350-12 located on the coil bushing 210-16 is planar. A support bar 211-16 is located in the center of the planar top surface of the dielectric layer 350-12. A planarizer 340-16 and a heat emissive layer 360-16 are sequentially disposed to surround the coil bushing 210-16. A plurality of unit coils 201-16, 202-16, and 203-16 are located inside the heat emissive layer 360-16.

Referring to FIG. 18, a dielectric layer 350-13 and a coil bushing 210-17 are sequentially disposed in the center of a top surface of a dome 312-17. The dome 312-17 has a planar bottom surface, but has a concave portion in the center of the top surface. The dielectric layer 350-13 is disposed on the concave portion and has a planar top surface. A top surface of the coil bushing 210-17 located on the dielectric layer 350-13 has a convex form. A support bar 211-17 is located in the center of the convex top surface of the coil bushing 210-17. A planarizer 340-17 and a heat emissive layer 360-17 are sequentially disposed to surround the coil bushing 210-17. A plurality of unit coils 201-17, 202-17, and 203-17 are located inside the heat emissive layer 360-17.

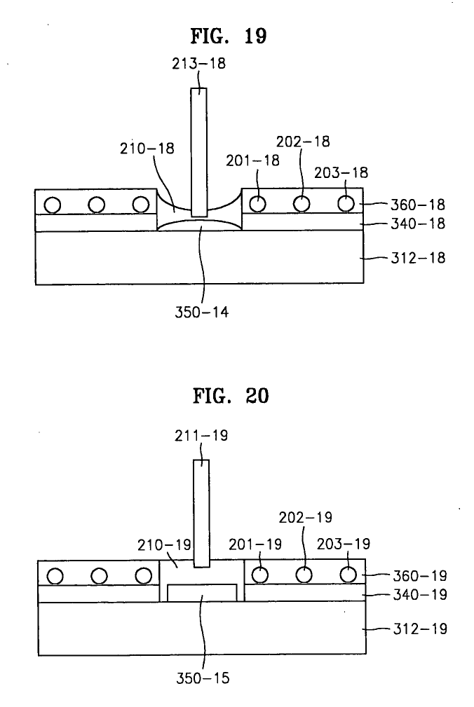

Referring to FIG. 19, a dielectric layer 350-14 and a coil bushing 210-18 are sequentially disposed in the center of a top surface of a dome 312-18. The dome 312-18 has planar bottom and top surfaces. A top surface of the dielectric layer 350-14 located on the dome 312-18 has a convex form. A top surface and bottom surface of the coil bushing 210-18 located on the dielectric layer 350-14 have a concave form and convex form, respectively. A support bar 211-18 is located in the center of the concave top surface of the coil bushing 210-18. A planarizer 340-18 and a heat emissive layer 360-18 are sequentially disposed to surround the coil bushing 210-18. A plurality of unit coils 201-18, 202-18, and 203-18 are located inside the heat emissive layer 360-18.

Referring to FIG. 20, a dielectric layer 350-12 is disposed in the center of a top surface of a dome 312-19. A coil bushing 210-19 is located on the top surface of the dome 312-19 to completely cover the dielectric layer 350-15. The dome 312-19, the dielectric layer 350-15, and the coil bushing 210-19 each have planar bottom and top surfaces. A support bar 211-19 is located in the center of the planar top surface of the coil bushing 210-19. A planarizer 340-19 and a heat emissive layer 360-19 are sequentially disposed to surround the coil bushing 210-19. A plurality of unit coils 201-19, 202-19, and 203-19 are located inside the heat emissive layer 360-19.

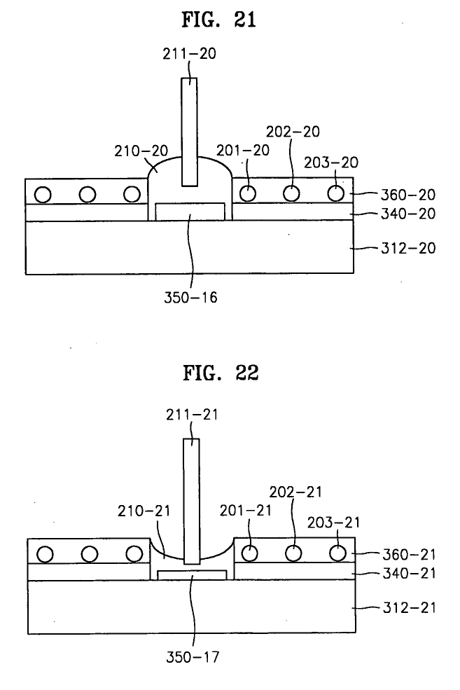

Referring to FIG. 21, a dielectric layer 350-16 is disposed in the center of a top surface of a dome 312-20. A coil bushing 210-20 is located on the top surface of the dome 312-20 to completely cover the dielectric layer 350-16. The dome 312-20 and the dielectric layer 350-16 each have planar bottom and top surfaces. While a bottom surface of the coil bushing 210-20 is planar, a top surface thereof has a convex form. A support bar 211-20 is located in the center of the convex top surface of the coil bushing 210-20. A planarizer 340-20 and a heat emissive layer 360-20 are sequentially disposed to surround the coil bushing 210-20. A plurality of unit coils 201-20, 202-20, and 203-20 are located inside the heat emissive layer 360-20.

Referring to FIG. 22, a dielectric layer 350-17 is disposed in the center of a top surface of a dome 312-21. A coil bushing 210-21 is located on the top surface of the dome 312-21 to completely cover the dielectric layer 350-17. The dome 312-21 and the dielectric layer 350-17 each have planar bottom and top surfaces. While a bottom surface of the coil bushing 210-21 is planar, a top surface thereof has a concave form. A support bar 211-21 is located in the center of the concave top surface of the coil bushing 210-21. A planarizer 340-21 and a heat emissive layer 360-21 are sequentially disposed to surround the coil bushing 210-21. A plurality of unit coils 201-21, 202-21, and 203-21 are located inside the heat emissive layer 360-21.

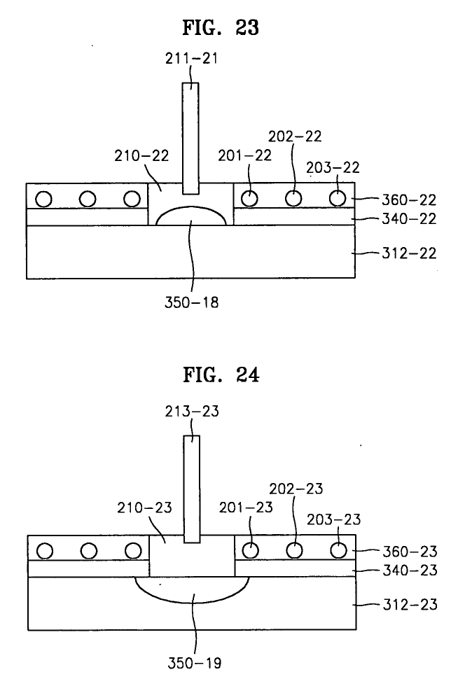

Referring to FIG. 23, a dielectric layer 350-18 is disposed in the center of a top surface of a dome 312-22. A coil bushing 210-22 is located on the top surface of the dome 312-22 to completely cover the dielectric layer 350-18. The dome 312-22 has planar bottom and top surfaces. A bottom surface of the dielectric layer 350-18 and a top surface of the coil bushing 210-22 are planar. However, a top surface of the dielectric layer 350-18 has a convex form. Also, a portion of a bottom surface of the coil bushing 210-22, which contacts the top surface of the dielectric layer 350-18, also has a convex form. A support bar 211-22 is located in the center of the top surface of the coil bushing 210-22. A planarizer 340-22 and a heat emissive layer 360-22 are sequentially disposed to surround the coil bushing 210-22. A plurality of unit coils 201-22, 202-22, and 203-22 are located inside the heat emissive layer 360-22.

Referring to FIG. 24, a dielectric layer 350-19 and a coil bushing 210-23 are sequentially disposed in the center of a top surface of a dome 312-23. While a bottom surface of the dome 312-23 is planar, a central portion of a top surface thereof has a concave form. A top surface of the dielectric layer 350-19 located on the concave portion is planar. A top surface of the coil bushing 210-23 located on the dielectric layer 350-19 also is planar. A support bar 211-23 is located in the center of the planar top surface of the coil bushing 210-23. A planarizer 340-23 and a heat emissive layer 360-23 are sequentially disposed to surround the coil bushing 210-23. A plurality of unit coils 201-23, 202-23, and 203-23 are located inside the heat emissive layer 360-23.

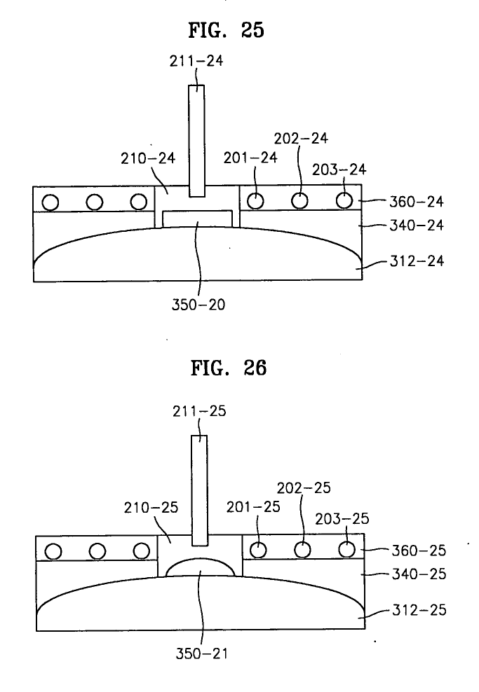

Referring to FIG. 25, while a bottom surface of a dome 312-24 is planar, a top surface thereof has a convex form. A dielectric layer 350-20 is disposed in the center of the convex top surface of the dome 312-24. A coil bushing 210-24 is located on the top surface of the dome 312-24 to completely cover the dielectric layer 350-20. The dielectric layer 350-20 and the coil bushing 210-24 each have a planar top surface. A support bar 211-24 is located in the center of the planar top surface of the coil bushing 210-24. A planarizer 340-24 and a heat emissive layer 360-24 are sequentially disposed to surround the coil bushing 210-24. A plurality of unit coils 201-24, 202-24, and 203-24 are located inside the heat emissive layer 360-24.

Referring to FIG. 26, while a bottom surface of a dome 312-25 is planar, a top surface thereof has a convex form. A dielectric layer 350-21 is disposed in the center of the convex top surface of the dome 312-25. A coil bushing 210-25 is located on the top surface of the dome 312-25 to completely cover the dielectric layer 350-21. Like the dome 312-25, a top surface of the dielectric layer 350-21 has a convex form. However, a top surface of the coil bushing 210-25 is planar. A support bar 211-25 is located in the center of the planar top surface of the coil bushing 210-25. A planarizer 340-25 and a heat emissive layer 360-25 are sequentially disposed to surround the coil bushing 210-25. A plurality of unit coils 201-25, 202-25, and 203-25 are located inside the heat emissive layer 360-25.

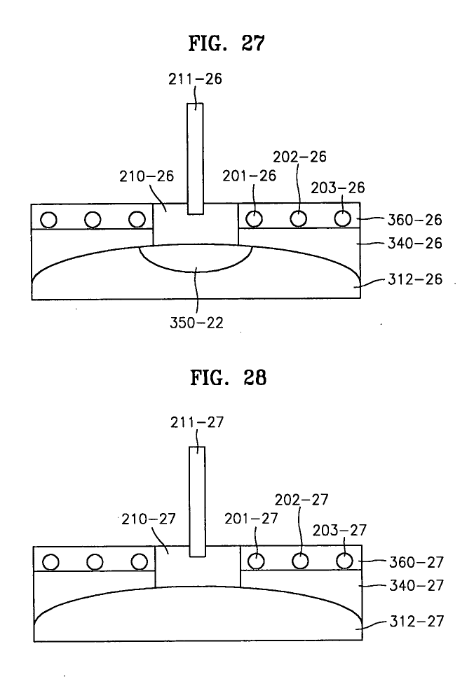

Referring to FIG. 27, while a bottom surface of a dome 312-26 is planar, a top surface thereof has a convex form. A dielectric layer 350-22 is inserted into the center of the convex top surface of the dome 312-26. A bottom surface of this dielectric layer 350-22 has a concave form. A coil bushing 210-26 is located on the dielectric layer 350-22. A bottom surface of the coil bushing 210-26, which contacts the top surface of the dielectric layer 350-22, has a convex form. However, a top surface of the coil bushing 210-26 is planar. A support bar 211-26 is located in the center of the top surface of the coil bushing 210-26. A planarizer 340-26 and a heat emissive layer 360-26 are sequentially disposed to surround the coil bushing 210-26. A plurality of unit coils 201-26, 202-26, and 203-26 are located inside the heat emissive layer 360-26.

Referring to FIG. 28, while a bottom surface of a dome 312-27 is planar, a top surface thereof has a convex form. A coil bushing 210-27 is located in the center of the top surface of the dome 312-27. While a bottom surface of the coil bushing 210-27 has a concave form, a top surface thereof is planar. A support bar 211-27 is located in the center of the planar top surface of the coil bushing 210-27. A planarizer 340-27 and a heat emissive layer 360-27 are sequentially disposed to surround the coil bushing 210-27. The planarizer 340-27 has a planar top surface, but has a curved bottom surface that contacts the top surface of the dome 312-27. A plurality of unit coils 201-27, 202-27, and 203-27 are located inside the heat emissive layer 360-27.

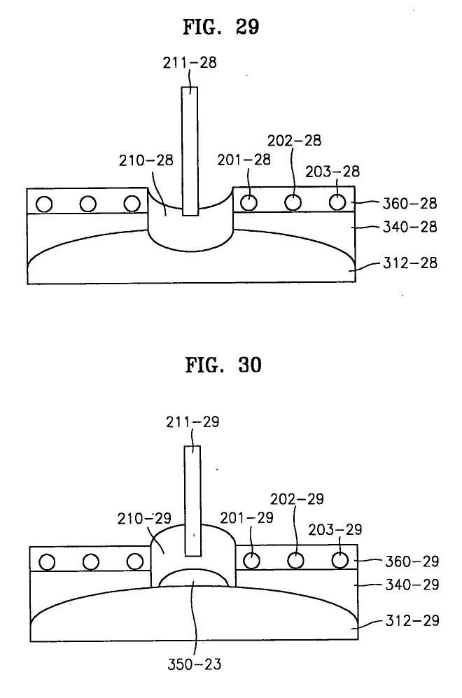

Referring to FIG. 29, while a bottom surface of a dome 312-28 is planar, a top surface thereof has a convex form. However, a central portion of the top surface of the dome 312-28 has a concave form. A coil bushing 210-28 is located on the concave portion. Thus, a bottom surface of the coil bushing 210-28 also has a concave form along a surface of the concave portion. Also, a top surface of the coil bushing 210-28 has a concave form. A support bar 211-28 is located in the center of the concave top surface of the coil bushing 210-28. A planarizer 360-28 and a heat emissive layer 340-28 are sequentially disposed to surround the coil bushing 210-28. The planarizer 340-28 has a planar top surface, but has a curved bottom surface that contacts the top surface of the dome 312-28. A plurality of unit coils 201-28, 202-28, and 203-28 are located inside the heat emissive layer 360-28.

Referring to FIG. 30, while a bottom surface of a dome 312-29 is planar, a top surface thereof has a convex form. A dielectric layer 350-23 is located in the center of the convex top surface of the dome 312-29. A coil bushing 210-29 is located on the top surface of the dome 312-29 to completely cover the dielectric layer 350-23. Like the dome 312-29, a top surface of the dielectric layer 350-23 has a convex form. Also, a top surface of the coil bushing 210-29 has a convex form. A support bar 211-29 is inserted into the central top surface of the coil bushing 210-29. A planarizer 340-29 and a heat emissive layer 360-29 are sequentially disposed to surround the coil bushing 210-29. A plurality of unit coils 201-29, 202-29, and 203-29 are located inside the heat emissive layer 360-29.

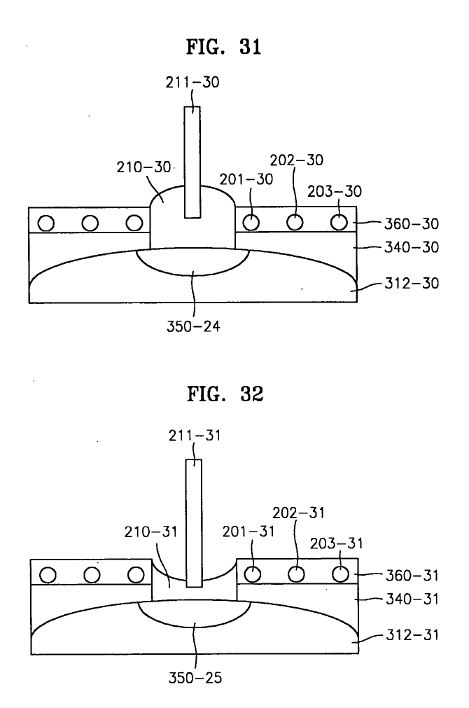

Referring to FIG. 31, while a bottom surface of a dome 312-30 is planar, a top surface thereof has a convex form. A dielectric layer 350-40 is inserted into the central top surface of the dome 312-30. A bottom surface of the dielectric layer 350-24 has a concave form. A coil bushing 210-30 is located on the dielectric layer 350-24. A bottom surface of the coil bushing 210-30, which contacts the top surface of the dielectric layer 350-24, has a convex form. A top surface of the coil bushing 210-30 has a convex form. A support bar 211-30 is located in the center of the convex top surface of the coil bushing 210-30. A planarizer 340-30 and a heat emissive layer 360-30 are sequentially disposed to surround the coil bushing 210-30. The planarizer 340-30 has a planar top surface, but has a curved bottom surface that contacts the top surface of the dome 312-30. A plurality of unit coils 201-30, 202-30, and 203-30 are located inside the heat emissive layer 360-30.

Referring to FIG. 32, while a bottom surface of a dome 312-31 is planar, a top surface thereof has a convex form. A dielectric layer 350-25 is inserted into the central top surface of the dome 312-31. A bottom surface of the dielectric layer 350-25 has a concave form. A coil bushing 210-31 is located on the dielectric layer 350-25. A bottom surface of the coil bushing 210-31, which contacts a top surface of the dielectric layer 350-25, has a convex form. A top surface of the coil bushing 210-31 has a concave form. A support bar 211-31 is located in the center of the concave top surface of the coil bushing 210-31. A planarizer 340-31 and a heat emissive layer 360-31 are sequentially disposed to surround the coil bushing 210-31. The planarizer 340-31 has a planar top surface, but has a curved bottom surface that contacts the top surface of the dome 312-31. A plurality of unit coils 201-31, 202-31, and 203-31 are located inside the heat emissive layer 360-31.

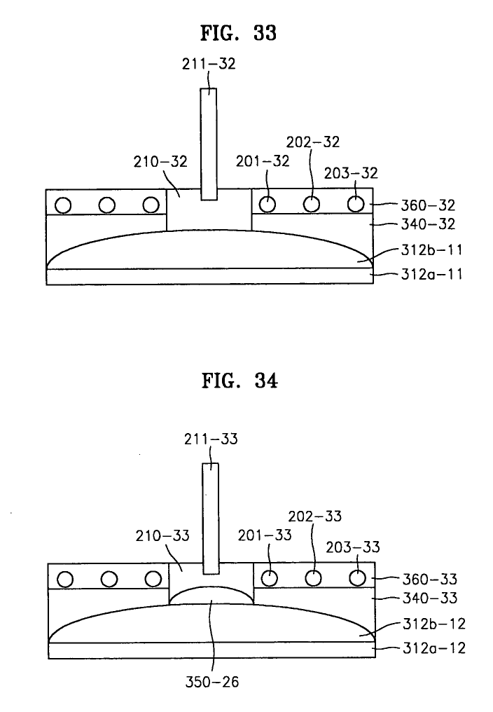

Referring to FIG. 33, a lower dome 312a-11 and an upper dome 312b-11 are sequentially disposed. The lower dome 312a-11 is formed of alumina and the upper dome 312b-11 is formed of ceramic, but the present invention is not limited thereto. A bottom surface of the lower dome 312a-11 is exposed to an inner space of a plasma chamber, and a top surface thereof is in contact with a bottom surface of the upper dome 312b-11. The lower dome 312a-11 has planar top and bottom surfaces. However, while the bottom surface of the upper dome 312b-11 is planar, a top surface thereof has a convex form. A coil bushing 210-32 is located on the upper dome 312b-11. A bottom surface of the coil bushing 210-32, which contacts the top surface of the upper dome 312b-11, also has a convex form. A top surface of the coil bushing 210-32 is planar. A support bar 211-32 is located in the planar top surface of the coil bushing 210-32. A planarizer 340-32 and a heat emissive layer 360-32 are sequentially disposed to surround the coil bushing 210-32. The planarizer 340-32 has a planar top surface, but has a curved bottom surface that contacts the top surface of the upper dome 312b-11. A plurality of unit coils 201-32, 202-32, and 203-32 are located inside the heat emissive layer 360-32.

Referring to FIG. 34, a lower dome 312a-12 and an upper dome 312b-12 are sequentially disposed. The lower dome 312a-12 has planar top and bottom surfaces. While a bottom surface of the upper dome 312b-12 is planar, a top surface thereof has a convex form. A dielectric layer 350-12 and a coil bushing 21-33 are sequentially disposed in the center of the top surface of the upper dome 312b-12. Like the top surface of the upper dome 312b-12, a top surface of the dielectric layer 350-26 has a convex form. A top surface of the coil bushing 210-33 is planar. A support bar 211-33 is located on the planar top surface of the coil bushing 210-33. A planarizer 340-33 and a heat emissive layer 360-33 are sequentially disposed to surround the coil bushing 210-33. The planarizer 340-33 has a planar top surface, but has a curved bottom surface that contacts the top surface of the upper dome 312b-12. A plurality of unit coils 201-33, 202-33, and 203-33 are located inside the heat emissive layer 360-33.

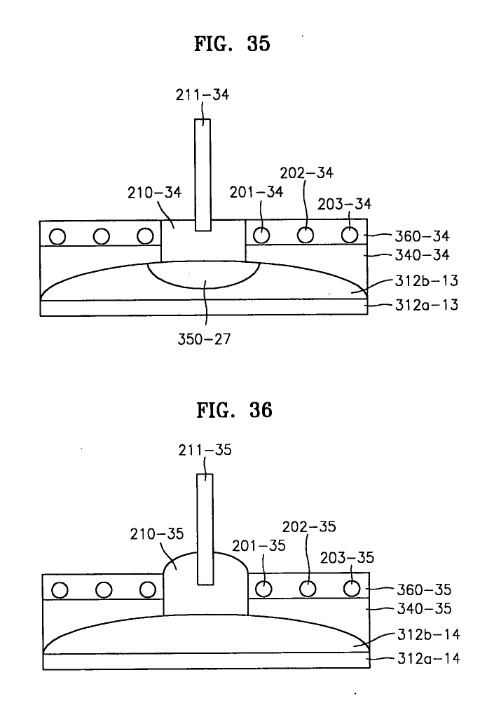

Referring to FIG. 35, a lower dome 312a-13 and an upper dome 312b-13 are sequentially disposed. The lower dome 312a-13 has planar top and bottom surfaces. While a bottom surface of the upper dome 312b-13 is planar, a top surface thereof has a convex form. A dielectric layer 350-27 is inserted into the central top surface of the upper dome 312b-13. A bottom surface of the dielectric layer 350-27 has a concave form. A coil bushing 210-34 is located on a top surface of the dielectric layer 350-27. A bottom surface of the coil bushing 210-34, which contacts the top surface of the dielectric layer 350-27, has a convex form, but a top surface thereof is planar. A support bar 211-34 is located in the central top surface of the coil bushing 210-34. A planarizer 340-34 and a heat emissive layer 360-34 are sequentially disposed to surround the coil bushing 210-34. The planarizer 340-34 has a planar top surface, but has a curved bottom surface that contacts the top surface of the upper dome 312b-13. A plurality of unit coils 201-34, 202-34, and 203-34 are located inside the heat emissive layer 360-34.

Referring to FIG. 36, a lower dome 312a-14 and an upper dome 312b-14 are sequentially disposed. A bottom surface of the lower dome 312a-14 is exposed to an inner space of a plasma chamber, and a top surface thereof is in contact with a bottom surface of the upper dome 312b-14. The lower dome 312a-14 has planar top and bottom surfaces. While the bottom surface of the upper dome 312b-14 is planar, a bottom surface thereof has a convex form. A coil bushing 210-35 is located on the upper dome 312b-14. A bottom surface of the coil bushing 210-35, which contacts the top surface of the upper dome 312b-14, has a convex form. A top surface of the coil bushing 210-35 has a convex form. A support bar 211-35 is inserted into the central top surface of the coil bushing 210-35. A planarizer 340-35 and a heat emissive layer 360-35 are sequentially disposed to surround the coil bushing 210-35. The planarizer 340-35 has a planar top surface, but has a curved bottom surface that contacts the top surface of the upper dome 312b-14. A plurality of unit coils 201-35, 202-35, and 203-35 are located inside the heat emissive layer 360-35.

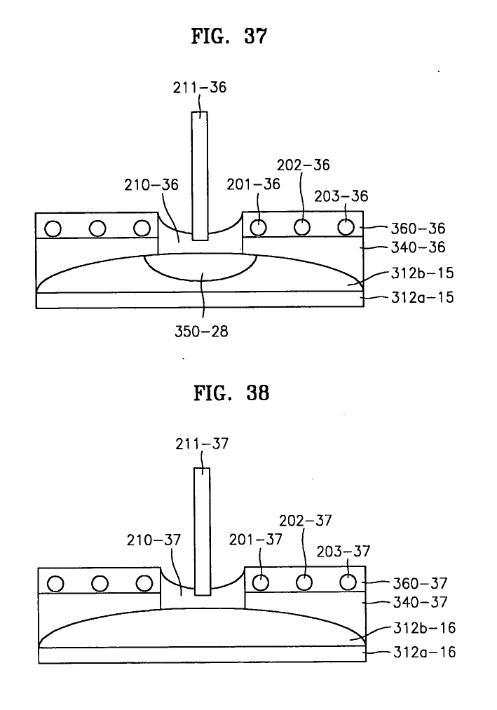

Referring to FIG. 37, a lower dome 312a-15 and an upper dome 312b-15 are sequentially disposed. The lower dome 312a-15 has planar top and bottom surfaces. While a bottom surface of the upper dome 312b-15 is planar, a top surface thereof has a convex form. A dielectric layer 350-28 is inserted into the central top surface of the upper dome 312b-15. A bottom surface of the dielectric layer 350-28 has a concave form. A coil bushing 210-36 is located on a top surface of the dielectric layer 350-28. A bottom surface of the coil bushing 210-36, which contacts the top surface of the dielectric layer 350-28, has a convex form, but a top surface thereof has a concave form. A support bar 211-36 is located in the center of the top surface of the coil bushing 210-36. A planarizer 340-36 and a heat emissive layer 360-36 are sequentially disposed to surround the coil bushing 210-36. The planarizer 340-36 has a planar top surface, but has a curved bottom surface that contacts the top surface of the upper dome 312b-15. A plurality of unit coils 201-36, 202-36, and 203-36 are located inside the heat emissive layer 360-36.

Referring to FIG. 38, a lower dome 312a-16 and an upper dome 312b-16 are sequentially disposed. The lower dome 312a-16 has planar top and bottom surfaces. While a bottom surface of the upper dome 312b-16 is planar, a top surface thereof has a convex form. A coil bushing 210-37 is located on the upper dome 312b-016. A bottom surface of the coil bushing 210-37, which contacts the top surface of the upper dome 312b-16, has a convex form, but a top surface thereof has a concave form. A support bar 211-37 is inserted into the central top surface of the coil bushing 210-37. A planarizer 340-37 and a heat emissive layer 360-37 are sequentially disposed to surround the coil bushing 210-37. The planarizer 340-37 has a planar top surface, but has a curved bottom surface that contacts the top surface of the upper dome 312b-16. A plurality of unit coils 201-37, 202-37, and 203-37 are located inside the heat emissive layer 360-37.

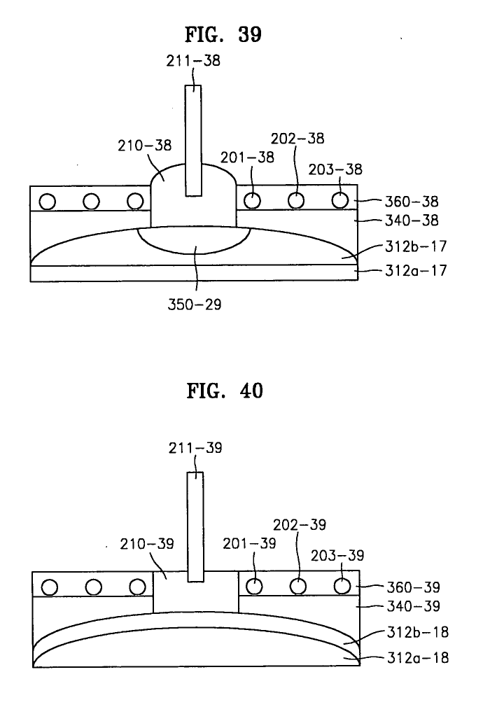

Referring to FIG. 39, a lower dome 312a-17 and an upper dome 312b-17 are sequentially disposed. The lower dome 312a-17 has planar top and bottom surfaces. While a bottom surface of the upper dome 312b-17 is planar, a top surface thereof has a convex form. A dielectric layer 350-29 is inserted into the central top surface of the upper dome 312b-15. A bottom surface of the dielectric layer 350-29 has a concave form. A coil bushing 210-38 is located on the dielectric layer 350-29. A bottom surface of the coil bushing 210-38, which contacts a top surface of the dielectric layer 350-29, has a convex form. Also, a top surface of the coil bushing 210-38 has a convex form. A support bar 211-38 is inserted into the central top surface of the coil bushing 210-38. A planarizer 340-38 and a heat emissive layer 360-38 are sequentially disposed to surround the coil bushing 210-38. The planarizer 340-38 has a planar top surface, but has a curved bottom surface that contacts the top surface of the upper dome 312b-17. A plurality of unit coils 201-38, 202-38, and 203-38 are located inside the heat emissive layer 360-38.

Referring to FIG. 40, a lower dome 312a-18 and an upper dome 312b-18 are sequentially disposed. While a bottom surface of the lower dome 312a-18 is planar, a top surface thereof has a convex form. The upper dome 312b-18 has convex top and bottom surfaces. A coil bushing 210-39 is located on the upper dome 312b-18. A bottom surface of the coil bushing 210-39, which contacts the top surface of the upper dome 312b-18, has a convex form, but a top surface thereof is planar. A support bar 211-39 is inserted into the central top surface of the coil bushing 210-39. A planarizer 340-39 and a heat emissive layer 360-39 are sequentially disposed to surround the coil bushing 210-39. The planarizer 340-39 has a planar top surface, but has a curved bottom surface that contacts the top surface of the upper dome 312b-18. A plurality of unit coils 201-39, 202-39, and 203-39 are located inside the heat emissive layer 360-39.

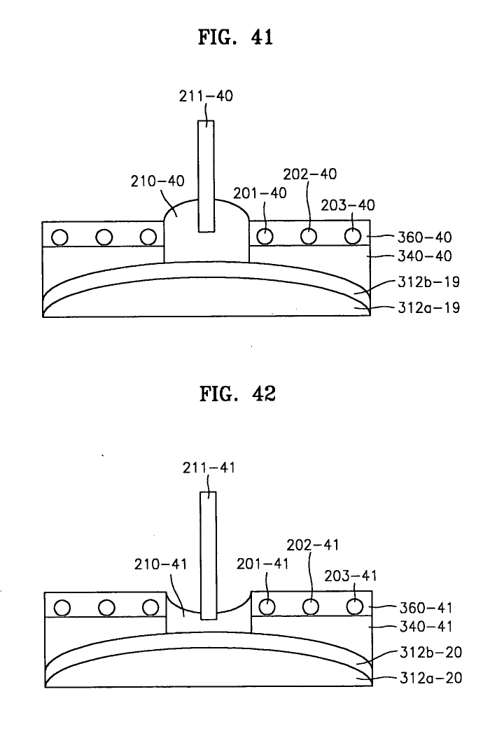

Referring to FIG. 41, a lower dome 312a-19 and an upper dome 312b-19 are sequentially disposed. While a bottom surface of the lower dome 312a-19 is planar, atop surface thereof has a convex form. The upper dome 312b-19 has convex top and bottom surfaces. A coil bushing 210-40 is located on the upper dome 312b-19. A bottom surface of the coil bushing 210-40, which contacts the top surface of the upper dome 312b-19, has a convex form. Also, a top surface of the coil bushing 210-40 has a convex form. A support bar 211-40 is inserted into the central top surface of the coil bushing 210-40. A planarizer 340-40 and a heat emissive layer 360-40 are sequentially disposed to surround the coil bushing 210-40. The planarizer 340-40 has a planar top surface, but has a curved bottom surface that contacts the top surface of the upper dome 312b-19. A plurality of unit coils 201-40, 202-40, and 203-40 are located inside the heat emissive layer 360-40.

Referring to FIG. 42, a lower dome 312a-20 and an upper dome 312b-20 are sequentially disposed. While a bottom surface of the lower dome 312a-20 is planar, a top surface thereof has a convex form. The upper dome 312b-20 has convex top and bottom surfaces. A coil bushing 210-41 is located on the upper dome 312b-20. A bottom surface of the coil bushing 210-41, which contacts the top surface of the upper dome 312b-20, has a convex form, but a top surface thereof has a concave form. A support bar 211-41 is inserted into the central top surface of the coil bushing 210-41. A planarizer 340-41 and a heat emissive layer 360-41 are sequentially disposed to surround the coil bushing 210-41. The planarizer 340-41 has a planar top surface, but has a curved bottom surface that contacts the top surface of the upper dome 312b-20. A plurality of unit coils 201-41, 202-41, and 203-41 are located inside the heat emissive layer 360-41.

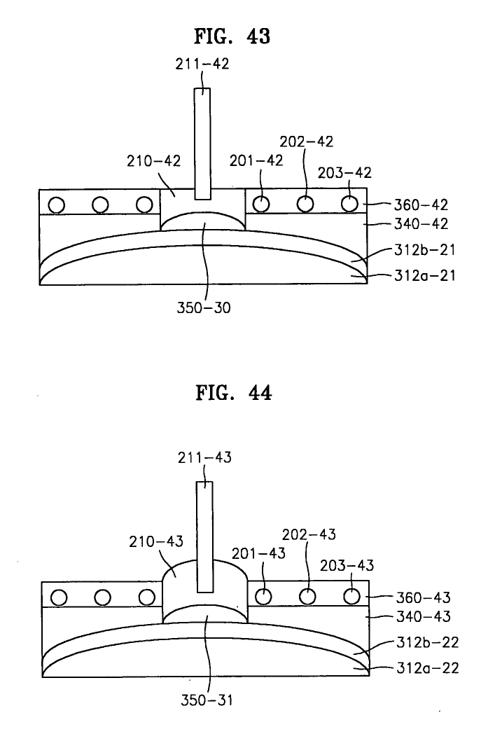

Referring to FIG. 43, a lower dome 312a-21 and an upper dome 312b-21 are sequentially disposed. While a bottom surface of the lower dome 312a-21 is planar, a top surface thereof has a convex form. The upper dome 312b-21 has convex top and bottom surfaces. A dielectric layer 350-30 and a coil bushing 210-42 are sequentially disposed in the center of the top surface of the upper dome 312b-21. Like the top surface of the upper dome 312b-21, a top surface of the dielectric layer 350-30 has a convex form. A top surface of the coil bushing 210-42 is planar. A support bar 211-42 is inserted into the central top surface of the coil bushing 210-42. A planarizer 340-42 and a heat emissive layer 360-42 are sequentially disposed to surround the coil bushing 210-42. The planarizer 340-42 has a planar top surface, but has a curved bottom surface that contacts the top surface of the upper dome 312b-21. A plurality of unit coils 201-42, 202-42, and 203-42 are located inside the heat emissive layer 360-42.

Referring to FIG. 44, a lower dome 312a-22 and an upper dome 312b-22 are sequentially disposed. While a bottom surface of the lower dome 312a-22 is planar, a top surface thereof has a convex form. The upper dome 312b-22 has convex top and bottom surfaces. A dielectric layer 350-31 and a coil bushing 210-43 are sequentially disposed in the center of the top surface of the upper dome 312b-22. Like the top surface of the upper dome 312b-22, a top surface of the dielectric layer 350-31 has a convex form. Also, a top surface of the coil bushing 210-43 has a convex form. A support bar 211-43 is inserted into the central top surface of the coil bushing 210-43. A planarizer 34043 and a heat emissive layer 360-43 are sequentially disposed to surround the coil bushing 210-43. The planarizer 340-43 has a planar top surface, but has a curved bottom surface that contacts the top surface of the upper dome 312b-22. A plurality of unit coils 201-43, 202-43, and 203-43 are located inside the heat emissive layer 360-43.

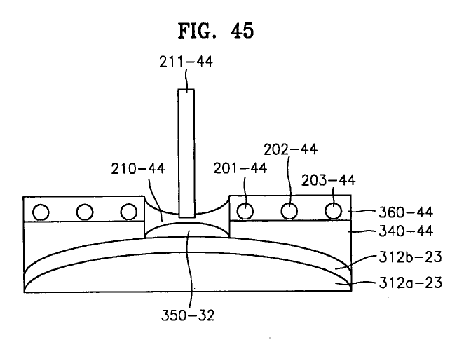

Referring to FIG. 45, a lower dome 312a-23 and an upper dome 312b-23 are sequentially disposed. While a bottom surface of the lower dome 312a-23 is planar, a top surface thereof has a convex form. The upper dome 312b-23 has convex top and bottom surfaces. A dielectric layer 350-32 and a coil bushing 210-44 are sequentially disposed in the center of the top surface of the upper dome 312b-23. Like the top surface of the upper dome 312b-23, a top surface of the dielectric layer 350-32 has a convex form. However, a top surface of the coil bushing 210-44 has a concave form. A support bar 211-44 is located in the center of the concave top surface of the coil bushing 210-44. A planarizer 340-44 and a heat emissive layer 360-44 are sequentially disposed to surround the coil bushing 210-44. The planarizer 340-44 has a planar top surface, but has a curved bottom surface that contacts the top surface of the upper dome 312b-23. A plurality of unit coils 201-44, 202-44, and 203-44 are located inside the heat emissive layer 360-44.

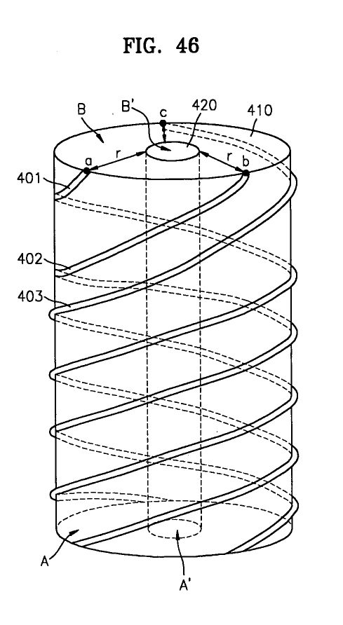

FIG. 46 shows a plasma source coil according to another embodiment of the present invention.

Referring to FIG. 46, the plasma source coil is comprised of an insulating pillar 410 having a bottom surface A and a top surface B. This insulating pillar 410 is a circular cylinder, through which a conductive bushing pillar 420 is located in a vertical direction. Although the insulating pillar 410 and the bushing pillar 420 are illustrated as circular cylinders in FIG. 46, the present invention is not limited thereto. According to circumstances, the insulating pillar 410 or the bushing pillar 420 can be replaced by other various pillars, such as square pillars or polygonal pillars. Also, the insulating pillar 410 may be replaced by a vacant space. A bottom surface A′ of the bushing pillar 420 is on the same plane with the bottom surface A of the insulating pillar 410, and a top surface B′ of the bushing pillar 420 is on the same plane with the top surface B of the insulating pillar 410.

A plurality of unit coils, for example, a first unit coil 401, a second unit coil 402, and a third unit coil 403, diverge from the circumference of the top surface B′ of the bushing pillar 420 and have curved shapes on the top surface B of the insulating pillar 410. Although only three unit coils are shown in FIG. 46, which is intended merely to be illustrative, a greater number of unit coils than m coils (here, m≧2, m is an integer) can be used. The first, second, and third unit coils 401, 402, and 403 are located in a spiral shape along the circumference of the top surface B of the insulating pillar 410. Each of the first, second, and third unit coils 401, 402, and 403 has a number n of turns (here, n is a positive real number) and coils around the bushing pillar 420. Once each of the first, second, and third unit coils 401, 402, and 403 respectively reaches a certain point a, b, and c that is positioned at an edge of the insulating pillar 410 at radius (r) apart from the bushing pillar 420, the first, second, and third unit coils 401, 402, and 403 follow a helical trajectory around a lateral surface of the insulating pillar 410 until they reach the bottom surface A.

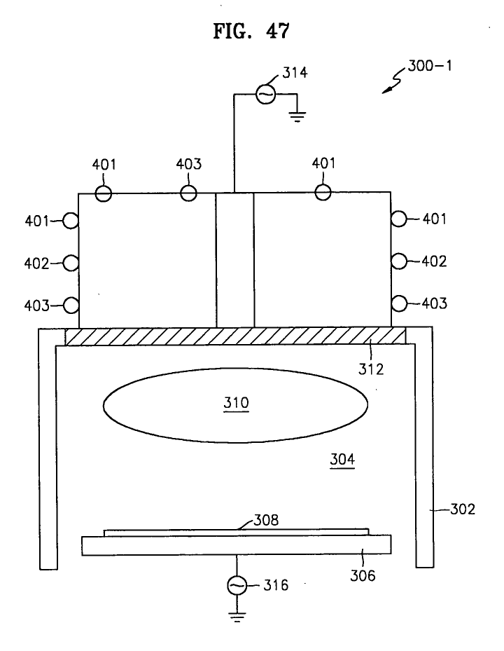

FIG. 47 is a cross-sectional view of a plasma chamber using the plasma source coil of FIG. 46.

Referring to FIG. 47, the structure of a plasma chamber 300-1 is similar to that of the plasma chamber 300 of FIG. 3 with the exception of a plasma source coil. In the plasma chamber 300-1, a certain size of inner space 304 is defined by outer walls 302 and a dome 312. Although the inner space 304 of the plasma chamber 300-1 is externally open in the drawing for simplicity, the inner space 304 is externally shut for practical use to maintain vacuum in the plasma chamber 300-1. A wafer support 306 is located at a lower portion of the inner space 304 to support semiconductor wafers 308 having certain patterns. An RF power supplier 316 is connected to the wafer support 306. An insulating pillar 410, a bushing pillar 420, and unit coils 401, 402, and 403, which constitute a plasma source coil, are arranged in a certain structure on an outer surface of the dome 312. According to circumstances, the insulating pillar 410 may be a vacant space. Since the structure of the plasma source coil was described with reference to FIG. 46, a description thereof will not be repeated here.

In this plasma chamber 300-1, the coil bushing 411 leads the density of plasma to reduce in the center of a wafer such that the plasma is uniformly distributed irrespective of positions of the wafer. Also, since the plasma chamber 300-1 has a 3-dimensional shape, the density of plasma can be increased, and the resistance can be increased due to the extending lengths of coils. Thus, the plasma chamber 300-1 of the present invention enhances various characteristics, such as etch selectivity, etch rate, and reproducibility.

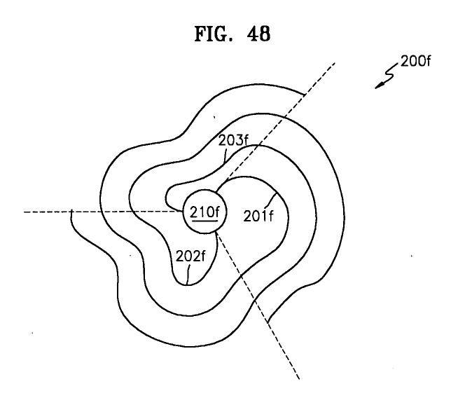

FIG. 48 is a plan view of a plasma source coil according to another embodiment of the present invention.

Referring to FIG. 48, the plasma source coil is comprised of a coil bushing 210f located in the center thereof and a plurality of unit coils 201f, 202f, and 203f. The coil bushing 210f is formed of a conductive material, for example, copper. Although not shown in the drawing, the coil bushing 210f is connected to an RF power supplier to receive power. Also, FIG. 48 shows that the coil bushing 210f has a circular shape, but the present invention is not limited to the circular shape of the coil bushing 210f. Of course, the coil bushing 210f can have various circular shapes, such as a circle and a circular donut, or polygonal shapes, such as a square, a square donut, a hexagon, a hexagonal donut, an octagon, an octagonal donut, and a triangle.

A first unit coil 201f, a second unit coil 202f, and a third unit coil 203f are arranged to diverge from the coil bushing 210f and spirally coil around the coil bushing 210f. In the present embodiment, three unit coils were exemplarily used, but the present invention is not limited to the foregoing number of unit coils. That is, the plasma source coil can include m unit coils (here, m≧2, and m is an integer). Each of the unit coils 201f, 202f, and 203f has a number n of turns (here, n is a positive real number). Since the first, second, and third unit coils 201f, 202f, and 203f diverge from the coil bushing 210f, the power that has been supplied to the coil bushing 210f are supplied to the first, second, and third unit coils 201f, 202f, and 203f.

Each of the first, second, and third unit coils 201f, 202f, and 203f coils around the coil bushing 210f while forming a wave-shaped curve instead of maintaining a certain interval apart from the center of the coil bushing 210f. Thus, each of the first, second, and third unit coils 201f, 202f, and 203f may be relatively far from or relatively close to the center of the coil bushing 210f according to positions. However, it is preferable to maintain a certain interval between any two of the first, second, and third unit coils 201f, 202f, and 203f. For each of the first, second, and third unit coils 201f, 202f, and 203f, the overall length L, the intensity H of magnetic field, and the impedance Z can be expressed as shown in Equations 1, 2, and 3, respectively.

L=2nπRₑ (1)

$$H = \frac{nI}{2 π {R}_{e}} \qquad ( 2 )$$

Z=2πnωRₑ (3)

In Equations 1, 2, and 3, I denotes the amount of current that flows through each of the unit coils 201f, 202f, and 203f, Rₑ denotes an effective radius of each coil from the center of the coil bushing 210f, n denotes the number of turns, and ω denotes the resonance frequency.

As can be seen from Equation 1, the entire length L is proportional to the effective radius Rₑ. In the plasma source coil of the present invention, since unit coils coil around a coil bushing located in the center of the plasma source coil and are curved in wave shapes, each unit coil has a longer entire length L than in typical single plasma source coils. As the entire length L increases, when the number n of turns is constant, the effective radius Rₑ also increases. As can be seen from Equation 2, the effective radius Rₑ is inversely proportional to the intensity H of magnetic field. Also, as can be seen from Equation 3, the effective radius Rₑ is proportional to the impedance Z. Hence, as the effective radius Rₑ increases, the intensity H of magnetic field decreases, but the impedance Z increases.

As is well known, the intensity H of magnetic field is proportional to the density of plasma in a plasma chamber or the ion flux, whereas the impedance Z is inversely proportional to the density of plasma or the ions flux. Here, the ion flux may refer to an ion flux in a coil or an ion flux in a plasma chamber. Since the ion flux in a coil is proportional to the ion flux in a plasma chamber in a certain range, it is not necessary to distinguish one from the other. As the ion flux is reduced with a decrease in the intensity H of magnetic field and an increase in the impedance Z, the density of plasma in an edge of a wafer also decreases. A decrease in the density of plasma leads to a slowdown of the etch rate. As a result, even if the diffusing speed of removing byproducts caused by chemical reactions during an etch process is high, since the etch rate also slows down, the rate ΔCD of change in critical dimension (CD) is reduced.

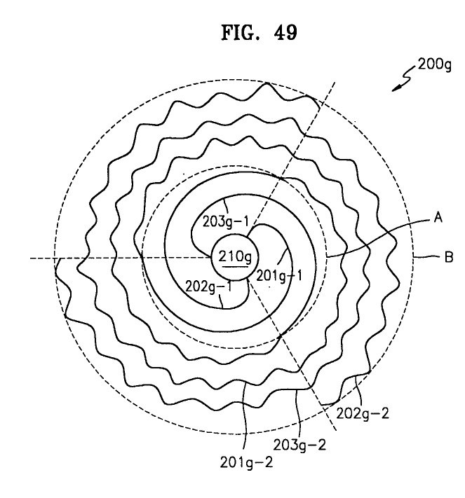

FIG. 49 is a plan view of a plasma source coil according to another embodiment of the present invention.

Referring to FIG. 49, the plasma source coil is comprised of a coil bushing 210g located in the center thereof, and a first plasma source coil portion A and a second plasma source coil portion B, which sequentially surround the coil bushing 210g. The first plasma source coil portion A comprises first unit coils 201g-1, 202g-1, and 203g-1, which diverge from the coil bushing 210g and coil around the coil bushing 210g. The second plasma source coil portion B comprises second unit coils 201g-2, 202g-2, and 203g-2, which extend from the first unit coils 201g-1, 202g-1, and 203g-1, respectively, and coil around the first plasma source coil portion A.

More specifically, the coil bushing 210g, located in the center of the first plasma source coil portion A, is formed of a conductive material, for example, copper. The first unit coils 201g-1, 202g-1, and 203g-1, which are also formed of a conductive material, for example, copper, diverge from the coil bushing 210g. Although only three unit coils 201g-1, 202g-1, and 203g-1 are shown in the drawing, which is intended merely to be illustrative, it is obvious that a greater number of unit coils than m coils (m≧2, and m is an integer) can be used. The first unit coils 201g-1, 202g-1, and 203g-1 are located in a spiral shape along the circumference of the coil bushing 210g. Each of the first unit coils 201g-1, 202g-1, and 203g-1 has a number n of turns (n is a positive real number) and coils around the coil bushing 210g.

The second unit coils 201g-2, 202g-2, and 203g-2, located in the second plasma source coil portion B, diverge from the first unit coils 201g-1, 202g-1, and 203g-1, respectively. That is, the second unit coil 201g-2 diverges from the first unit coil 201g-1, the second unit coil 202g-2 diverges from the first unit coil 202g-1, and the second unit coil 203g-2 diverges from the first unit coil 203g-1. The second unit coils 201g-2, 202g-2, and 203g-2 are curved in wave shapes and coil around the first plasma source coil portion A. Thus, the second unit coils 201g-2, 202g-2, and 203g-2 may be relatively far from or relatively close to the first plasma source coil portion A according to positions. However, it is preferable to maintain a certain interval between any two of the second unit coils 201g-2, 202g-2, and 203g-2.

In the present embodiment, since the second unit coils 201g-2, 202g-2, and 203g-2 in the second plasma source coil portion B are curved in wave shapes and coil around the first plasma source coil portion A, the plasma source coil has a longer entire length L than conventional single plasma source coils. As the entire length L increases, when the number n of turns is constant, the effective radius Rₑ also increases. As the effective radius Rₑ increases, the intensity H of magnetic field decreases, but the impedance Z increases. Hence, as the ion flux is reduced with a decrease in the intensity H of magnetic field and an increase in the impedance Z, the density of plasma in an edge of a wafer also decreases. As described with reference to FIG. 48, a decrease in the density of plasma leads to a slowdown of the etch rate. As a result, even if the diffusing speed of removing byproducts caused by chemical reactions during an etch process is high, since the etch rate also slows down, the rate ΔCD is reduced.

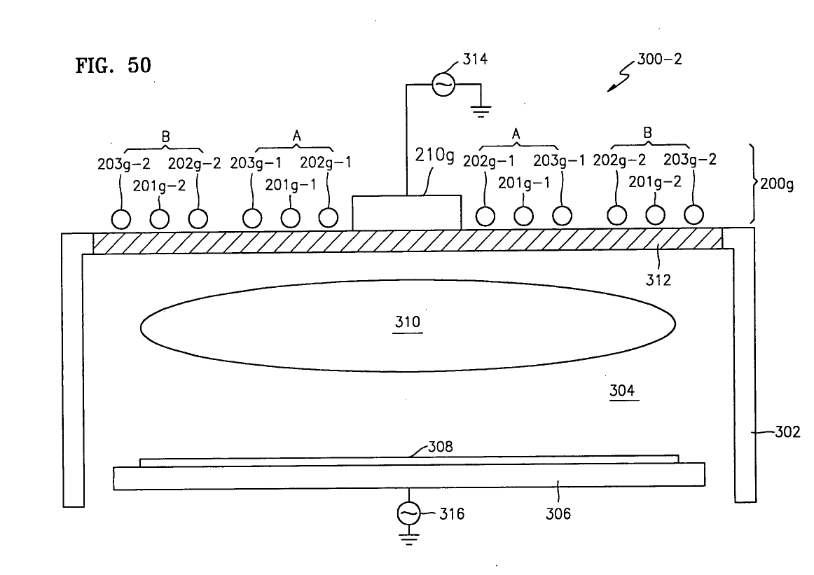

FIG. 50 is a cross-sectional view of a plasma chamber using the plasma source coil of FIG. 49.

Referring to FIG. 50, the structure of a plasma chamber 300-2 is similar to that of the plasma chamber 300 of FIG. 3 with the exception of a plasma source coil 200g. Since the operation and effect of the plasma chamber 300-2 are the same as those of the plasma chamber 300 as described with reference to FIG. 3, a description thereof will not be repeated here. The plasma chamber 300-2 comprises the plasma source coil 200g, which is made up of a first plasma source coil portion A and a second plasma source coil portion B. Since the plasma source coil 200g of FIG. 50 is the same as the plasma source coil as described with reference to FIG. 49, a description thereof will not be repeated here.

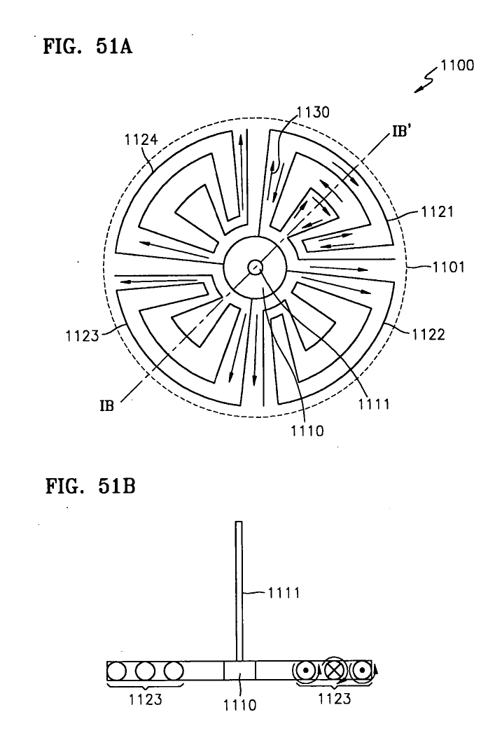

FIG. 51A is a plan view of a plasma source coil according to another embodiment of the present invention, and FIG. 51B is a cross-sectional view taken along line IB-IB′ of FIG. 51A.

Referring to FIGS. 51A and 51B, a plasma source coil 1100 of the present embodiment comprises a conductive bushing 1110. The conductive bushing 1110 is connected to a power applying line 1111, through which an RF current flows from an RF power supplier into the conductive bushing 1110. Four coil lines 1121, 1122, 1123, and 1124 diverge from edges of the conductive bushing 1110 and are located inside a circular boundary line 1101. An RF current flows from the conductive bushing 1110 into the respective coil lines 1121, 1122, 1123, and 1124. The first coil line 1121 and the third coil line 1123 are located in an opposite direction, and the second coil line 1122 and the fourth coil line 1124 are located in an opposite direction.

The first coil line 1121, which diverges from the conductive bushing 1110, extends from a point A toward a circular boundary line 1101, which is illustrated with a dotted line and defines the area of the plasma source coil 1100, and turns at a certain position to extend along the boundary line 1101. After that, the first coil line 1121 extends further as indicated by arrows 1130 of FIG. 51A and finally is grounded (not shown) adjacent to the boundary line 1101, i.e., at a point B.

The second coil line 1122 diverges from the conductive bushing 1110 adjacent to a position of the plasma source coil 1100, where the first coil line 1121 extends toward the boundary line 1101 and is grounded. The arrangement of the second coil line 1122 is similar to that of the first coil line 1121. The third coil line 1123 diverges from the conductive bushing 1110 at a position of the plasma source coil 1100, where the second coil line 1122 extends toward the boundary line 1101 and is grounded. Likewise, the fourth coil line 1124 diverges from the conductive bushing 1110 at a position of the plasma source coil 1100, where the third coil line 1123 extends toward the boundary line 1101 and is grounded. The arrangement of the third coil line 1123 or the fourth coil line 1124 is the same as that of the first coil line 1121 or the second coil line 1122.

In this plasma source coil 1100, RF currents flow through adjacent portions of each coil line in the opposite directions. For example, in the first coil line 1121, as indicated by the arrows 1130, RF currents flow through adjacent portions of the first coil line 1121 in the opposite directions. Hence, as indicated by arrows of FIG. 51B, magnetic fields generated by the RF currents that flow through the adjacent portions of the first coil line 1121 are in the same direction. Consequently, the magnetic fields do not counterbalance one another but are reinforced.

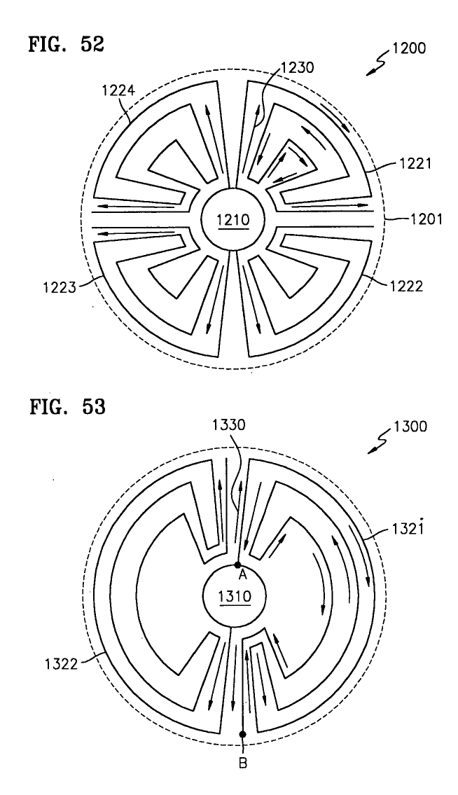

FIG. 52 is a plasma source coil according to another embodiment of the present invention.

Referring to FIG. 52, the structure of the plasma source coil 1200 is similar to that of the plasma source coil of FIG. 51A with the exception of a position where each coil line diverges from a conductive bushing 1210. Specifically, in the plasma source coil 1100 of FIG. 51A, positions where the coil lines 1121, 1122, 1123, and 1124 diverge from the conductive bushing 1110 are spaced a regular interval apart from one another. However, in the plasma source coil 1200 of the present embodiment, positions where first through fourth coil lines 1221, 1222, 1223, and 1224 diverge from the conductive bushing 1210 are not located at regular intervals. The first coil line 1221 pairs with the fourth coil line 1224, and the second coil line 1222 pairs with the third coil line 1223. A pair of coil lines diverge from the conductive bushing 1210 at adjacent positions. The first and fourth coil lines 1221 and 1224 diverge from the conductive bushing 1210 at adjacent positions, and the second and third coil lines 1222 and 1223 diverge from the conductive bushing 1210 at adjacent positions. The plasma source coil 1200 of the present embodiment has the same effect as the plasma source coil 1100. That is, as indicated by arrows 1230, RF currents flow through adjacent portions of each coil line in the opposite directions. As a result, the intensity of magnetic field increases.

FIG. 53 is a plan view of a plasma source coil according to another embodiment of the present invention.

Referring to FIG. 53, the structure of the plasma source coil 1300 is similar to that of the plasma source coil 1100 of FIG. 51A, with the exception of the number of coil lines that diverge from a conductive bushing 1310. That is, while the plasma source coil 1100 includes four coil lines that diverge from the conductive bushing 1110, the plasma source coil 1300 of the present embodiment includes two coil lines that diverge from the conductive bushing 1310. The plasma source coil 1300 comprises the conductive bushing 1310, from which a first coil line 1321 and a second coil line 1322 diverge. A position of the plasma source coil 1300 where the first coil line 1321 diverges from the conductive bushing 1310 is directly opposite to a position where the second coil line 1322 diverges therefrom. The first coil line 1321 is located on the right of the plasma source coil 1300, and the second coil line 1322 is located on the left thereof.

The first coil line 1321, which diverges from the conductive bushing 1310, extends from a point A toward a circular boundary line, which is illustrated with a dotted line and defines the area of the plasma source coil 1300, and turns at a certain position adjacent to the boundary line to extend along the boundary line. After that, the first coil line 1321 extends further as indicated by arrows 1330 and finally is grounded (not shown) adjacent to the boundary line, i.e., at a point B. The arrangement of the second coil line 1322 is the same as that of the first coil line 1321. The plasma source coil 1300 of the present embodiment has the same effect as the plasma source coils of other foregoing embodiments. That is, as indicated by arrows 1330, RF currents flow through adjacent portions of each coil line in the opposite directions. As a result, the intensity of magnetic field increases.

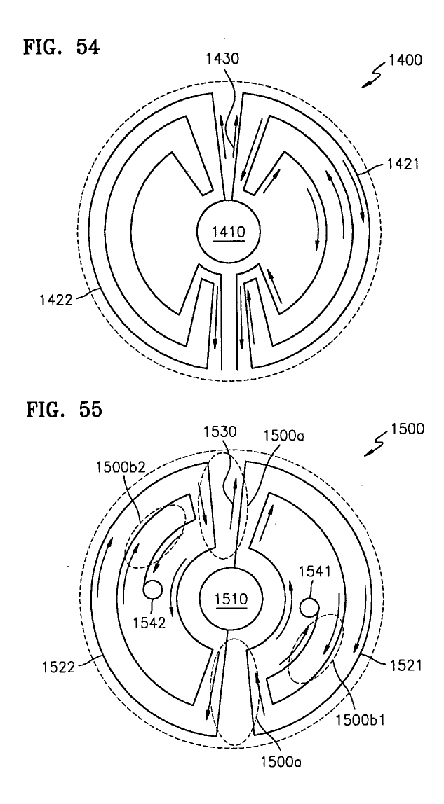

FIG. 54 is a plan view of a plasma source coil according to another embodiment of the present invention.

Referring to FIG. 54, the structure of the plasma source coil 1400 is similar to that of the plasma source coil 1300 of FIG. 53, with the exception of a position where each coil line diverges from a conductive bushing 1410. Specifically, in the plasma source coil 1300 of FIG. 53, a position where the first coil line 1321 diverges from the conductive bushing 1310 is directly opposite to a position where the second coil line 1322 diverges therefrom. However, in the plasma source coil 1400 of the present embodiment, a position where a first coil line 1421 diverges from the conductive bushing 1410 is adjacent to a position where a second coil line 1422 diverges therefrom. The first and second coil lines 1421 and 1422 diverge from adjacent positions of the conductive bushing 1410 and extend in the opposite directions. That is, the first coil line 1421 extends on the right of the conductive bushing 1410, and the second coil 1422 extends on the left thereof. Since the arrangement of the plasma source coil 1400 is similar to that of the plasma source coil 1300 of FIG. 53, a description thereof will not be repeated here. The plasma source coil 1400 of the present embodiment has the same effect as other foregoing plasma source coils. That is, as indicated by arrows 1430, RF currents flow through adjacent portions of each coil line in the opposite directions. As a result, the intensity of magnetic field increases.

FIG. 55 is a plan view of a plasma source coil according to another embodiment of the present invention.

Referring to FIG. 55, the plasma source coil 1500 of the present embodiment comprises a conductive bushing 1510, from which a first coil line 1521 and a second coil line 1522 diverge. A position where the first coil line 1521 diverges from the conductive bushing 1510 is directly opposite to a position where the second coil line 1522 diverges therefrom. The first coil line 1521 diverges from an upper position of the conductive bushing 1510 and is located in a right semicircle of a circular boundary line, which is illustrated with a dotted line and defines the area of the plasma source coil 1500. The second coil line 1522 diverges from a lower position of the conductive bushing 1510 and is located in a left semicircle of the boundary line. Here, the first coil line 1521 extends spirally in the right semicircle and the second coil line 1522 extends spirally in the right semicircle inside the circular boundary line.

More specifically, the first coil line 1521, which diverges from the conductive bushing 1510, extends toward the boundary line and turns at a certain position adjacent to the boundary line to extend along the boundary line. After that, the first coil line 1521 extends spirally as indicated by arrows 1530 and finally is connected to a first ground line 1541 that is located in the center of the right semicircle of the boundary line. Similarly, the second coil line 1522 diverges from the conductive bushing 1522, extends spirally in the left semicircle, and finally is connected to a second ground line 1542 that is located in the center of the left semicircle of the boundary line.

In the plasma source coil 1500 of the present embodiment, RF currents flow through some adjacent portions of the first coil line 1521 or the second coil line 1522 in the same direction. However, the RF current flows through the first coil line 1521 in the opposite direction from the RF current that flows through the second coil line 1522 at a portion 1500a where the first coil line 1521 is adjacent to the second coil line 1522. Thus, the intensity of magnetic field increases at the portion 1500a. Also, RF currents flow through adjacent portions of the first coil line 1541 in the opposite directions at a portion 1500b1 adjacent to the first ground line 1541. Similarly, RF currents flow through adjacent portions of the second coil line 1542 in the opposite directions at a portion 1500b2 adjacent to the second ground line 1542. The intensity of magnetic field increases at the portions 1500b1 and 1500b2.

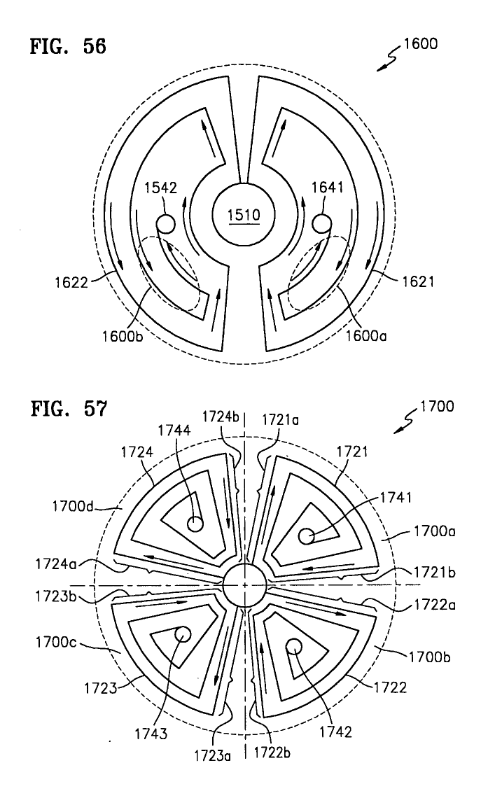

FIG. 56 is a plan view of a plasma source coil according to another embodiment of the present invention.

Referring to FIG. 56, the structure of the plasma source coil 1600 is similar to that of the plasma source coil 1500 of FIG. 55 with the exception of a position where each coil line diverges from a conductive bushing 1610. Specifically, in the plasma source 1500 of FIG. 55, a position where a first coil line 1521 diverges from the conductive bushing 1510 is directly opposite to a position where a second coil line 1522 diverges therefrom. However, in the plasma source coil 1600, a position where a first coil line 1621 diverges from the conductive bushing 1510 is adjacent to a position where a second coil line 1622 diverges therefrom. The first coil line 1621, which diverges from the conductive bushing 1610, extends toward a circular boundary line, which is illustrated with a dotted line, and turns to the right at a certain position adjacent to the boundary line. After that, the first coil line 1621 extends spirally as indicated by arrows and finally is connected to a first ground line 1641. Likewise, the second coil line 1622 diverges from the conductive bushing 1610 at a position adjacent to the position where the first coil line 1621 diverges, extends spirally in a left semicircle of the boundary line, and finally is connected to a second ground line 1642.

In the plasma source coil 1600, RF currents flow through adjacent portions of the first coil line 1641 in the opposite directions at a portion 1600a adjacent to the first ground line 1641. Similarly, RF currents flow through adjacent portions of the second coil line 1642 in the opposite directions at a portion 1600b adjacent to the second ground line 1642. The intensity of magnetic field increases at the portions 1600a and 1600b.

FIG. 57 is a plan view of a plasma source coil according to another embodiment of the present invention.

Referring to FIG. 57, the plasma source coil 1700 of the present embodiment comprises a conductive bushing 1710 and has an area defined by a circular boundary line, which is illustrated with a dotted line and spaced a certain radius apart from the conductive bushing 1710. The area defined by the circular boundary line is divided into four regions, i.e., a first region 1700a, a second region 1700b, a third region 1700c, and a fourth region 1700d. A first coil line 1721 diverges from the conductive bushing 1710 and is located in the first region 1700a. A second coil line 1722 diverges from the conductive bushing 1710 and is located in the second region. A third coil line 1723 diverges from the conductive bushing 1710 and is located in the third region 1700c. Also, a fourth coil line 1724 diverges from the conductive bushing 1710 and is located in the fourth region 1700d.

The first coil line 1721 diverges from the conductive bushing 1710 and extends in a fan blade shape to reach a first ground line 1741 located in the center of the first region 1700a. The second coil line 1722 diverges from the conductive bushing 1710 and extends in a fan blade shape to reach a second ground line 1742 located in the center of the second region 1700b. The third coil line 1723 diverges from the conductive bushing 1710 and extends in a fan blade shape to reach a third ground line 1743 located in the center of the third region 1700c. Also, the fourth coil line 1724 diverges from the conductive bushing 1710 and extends in a fan blade shape to reach a fourth ground line 1744 located in the center of the fourth region 1700d. More specifically, each of the first, second, third, and fourth coil lines 1721, 1722, 1723, and 1724 extends radially from the conductive bushing 1710 toward the boundary line, then extends parallel to the boundary line, then goes back toward the conductive bushing 1710, then extends parallel to the conductive bushing 1710, and then repeats the above trajectory to reach the first, second, third, or fourth ground line 1741, 1742, 1743, or 1744.

In this arrangement, a first portion 1721a of the first coil line 1721 is located adjacent to a second portion 1724b of the fourth coil line 1724, and a second portion 1721b of the first coil line 1721 is located adjacent to a first portion 1722a of the second coil line 1722. A second portion 1722b of the second coil line 1722 is located adjacent to a first portion 1723a of the third coil line 1723, and a second portion 1723b of the third coil line 1723 is located adjacent to a first portion 1724a of the fourth coil line 1724. As indicated by arrows, RF currents flow through these adjacent portions (1721a and 1724b, 1721b and 1722a, 1722b and 1723a, and 1723b and 1724a) of the coil lines 1721, 1722, 1723, and 1724, in the opposite directions. Thus, the intensity of magnetic field increases between the first portion 1721a of the first coil line 1721 and the second portion 1724b of the fourth coil 1724, the second portion 1721b of the first coil line 1721 and the first portion 1722a of the second coil line 1722, the second portion 1722b of the second coil line 1722 and the first portion 1723a of the third coil line 1723, and the second portion 1723b of the third coil line 1723 and the first portion 1724a of the fourth coil line 1724.

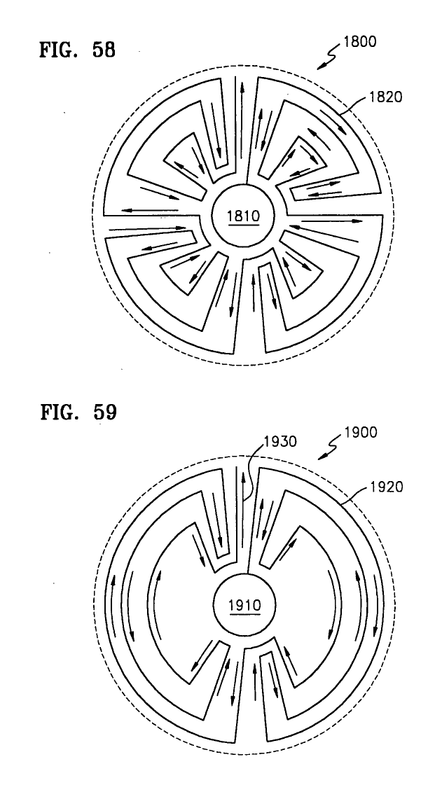

FIG. 58 is a top plan view of a plasma source coil according to another embodiment of the present invention.

Referring to FIG. 58, the plasma source coil 1800 of the present embodiment is different from the above-described other embodiments in that only one coil line 1820 diverges from a conductive bushing 1810. That is, the coil line 1820 diverges from the conductive bushing 1810 and extends in the shape of four fan blades in a circular boundary line, which is illustrated with a dotted line. More specifically, the coil line 1820 extends from the conductive bushing 1810 toward the boundary line and then extends parallel to the boundary line. After extending by less than a ¼ the circumference of the boundary line, the coil line 1820 goes back toward the conductive bushing 1810, then extends parallel to the conductive bushing 1810, and then repeats the above trajectory of a fan blade. The coil 1820 repeats this process four times as indicated by arrows. In this arrangement, many portions of the coil line 1820 are located adjacent to one another, and RF currents flow through the adjacent portions in the opposite directions. Thus, the intensity of magnetic field increases between the adjacent portions of the coil line 1820.

FIG. 59 is a plan view of a plasma source coil according to another embodiment of the present invention.

Referring to FIG. 59, the structure of the plasma source coil 1900 of the present embodiment is similar to that of the plasma source coil 1800 of FIG. 58, except that the plasma source coil 1900 has the shape of two semicircles. That is, in the plasma source coil 1900, one coil line 1920 diverges from a conductive bushing 1910 and extends inside a circular boundary line, which is illustrated with a dotted line. The coil line 1920 extends in a right semicircle of the boundary line to form a fan blade shape and then extends in a left semicircle of the boundary line to form another fan blade shape. In the plasma source coil 1900, as indicated by arrows 1930, RF currents flow through adjacent portions of the coil line 1920 in the opposite directions. Thus, the intensity of magnetic field increases between the adjacent portions of the coil line 1920.

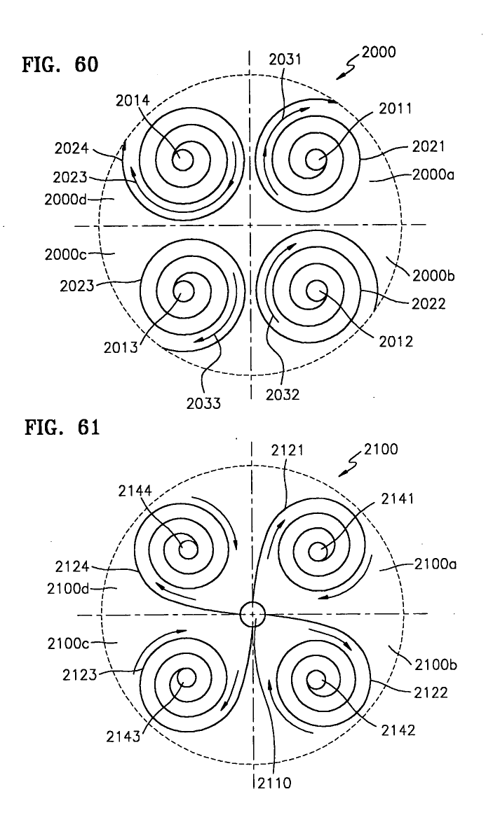

FIG. 60 is a plan view of a plasma source coil according to another embodiment of the present invention.

Referring to FIG. 60, in the plasma source coil 2000 of the present embodiment, an area is defined by a circular boundary line, which is illustrated with a dotted line and divided into a first region 2000a, a second region 2000b, a third region 2000c, and a fourth region 2000d. A first conductive bushing 2011 is located in the center of the first region 2000a, and a second conductive bushing 2012 is located in the center of the second region 2000b. A third conductive bushing 2013 is located in the center of the third region 2000c, and a fourth conductive bushing 2014 is located in the center of the fourth region 2000d. A first coil line 2021 diverges from the first conductive bushing 2011 and turns spirally clockwise inside the first region 2000a to reach the boundary line. Likewise, a second coil line 2022 diverges from the second conductive bushing 2012 and turns spirally clockwise inside the second region 2000b to reach the boundary line. Third and fourth coil lines 2023 and 2024 extend in the same manner as the first and second coil lines 2021 and 2022.

In this arrangement, RF currents flow through adjacent portions of each of the coil lines 2021, 2022, 2023, and 2024 in the same direction. Thus, the intensity of magnetic field does not increase in the adjacent portions of each coil line. However, there are a portion where the first coil line 2021 is adjacent to the second coil line 2022 between the first region 2000a and the second region 2000b, a portion where the second coil line 2022 is adjacent to the third coil line 2023 between the second region 2000b and the third region 2000c, a portion where the third coil line 2023 is adjacent to the fourth coil line 2024 between the third region 2000c and the fourth region 2000d, and a portion where the fourth coil line 2024 is adjacent to the first coil line 2021 between the fourth region 2000d and the first region 2000a. As indicated by arrows, RF currents flow through two adjacent coil lines between two regions, in the opposite directions. Thus, the intensity of magnetic field increases at each of the portions where one coil line is adjacent to another coil line between the two regions.

FIG. 61 is a plan view of a plasma source coil according to another embodiment of the present invention.

Referring to FIG. 61, in the plasma source coil 2100 of the present embodiment, an area is defined by a circular boundary line, which is illustrated with a dotted line, and divided into a first region 2100a, a second region 2100b, a third region 2100c, and a fourth region 2100d. A conductive bushing 2110 is located in the center of the plasma source coil 2100. A first ground line 2141 is located in the center of the first region 2100a, and a second ground line 2142 is located in the center of the second region 2100b. A third ground line 2143 is located in the center of the third region 2100c, and a fourth ground line 2144 is located in the center of the fourth region 2100d. A first coil line 2121 diverges from the conductive bushing 2110 and extends spirally inside the first region 2100a to reach the first ground line 2141. Likewise, the second coil line 2122 diverges from the conductive bushing 2110 and extends spirally inside the second region 2100b to reach the second ground line 2142. Third and fourth coil lines 2123 and 2124 extend in the same manner as the first and second coil lines 2121 and 2122.

In this arrangement, RF currents flow through adjacent portions of each of the coil lines 2121, 2122, 2123, and 2124 in the same direction. Thus, the intensity of magnetic field does not increase in the adjacent portions of each coil line. However, there are a portion where the first coil line 2121 is adjacent to the second coil line 2122 between the first region 2100a and the second region 2100b, a portion where the second coil line 2122 is adjacent to the third coil line 2123 between the second region 2100b and the third region 2100c, a portion where the third coil line 2123 is adjacent to the fourth coil line 2124 between the third region 2100c and the fourth region 2100d, and a portion where the fourth coil line 2124 is adjacent to the first coil line 2121 between the fourth region 2100d and the first region 2100a. As indicated by arrows, RF currents flow through two adjacent coil lines between two regions, in the opposite directions. Thus, the intensity of magnetic field increases at each of the portions where one coil line is adjacent to another coil line between the two regions.

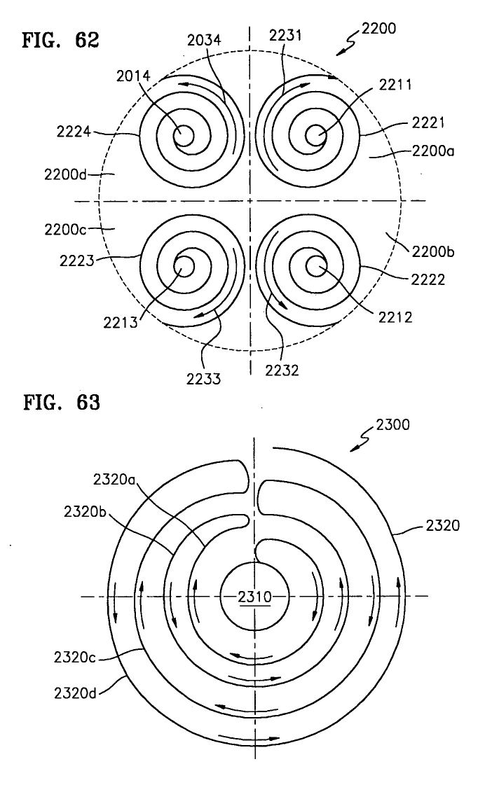

FIG. 62 is a plan view of a plasma source coil according to another embodiment of the present invention.

Referring to FIG. 62, the structure of the plasma source coil 200 is similar to that of the plasma source coil 2000 of FIG. 60, except that the plasma source coil 2200 comprises both clockwise coil lines and counterclockwise coil lines. More specifically, in the plasma source coil 2200, an area is defined by a circular boundary line, which is illustrated with a dotted line, and divided into a first region 2200a, a second region 2200b, a third region 2200c, and a fourth region 2200d. A first conductive bushing 2211 is located in the center of the first region 2200a, and a second conductive bushing 2212 is located in the center of the second region 2200b. A third conductive bushing 2213 is located in the center of the third region 2200c, and a fourth conductive bushing 2214 is located in the center of the fourth region 2200d.

A first coil line 2221 diverges from the first conductive bushing 2211 and turns spirally clockwise inside the first region 2200a to reach the boundary line. A second coil line 2222 diverges from the second conductive bushing 2212 and turns spirally counterclockwise inside the second region 2200b to reach the boundary line. A third coil line 2223 diverges from the third conductive bushing 2213 and turns spirally clockwise inside the third region 2200c. A fourth coil line 2224 diverges from the fourth conductive bushing 2214 and turns spirally counterclockwise inside the fourth region 2200d. That is, the first and third coil lines 2221 and 2223 each have a clockwise spiral structure, and the second and fourth coil lines 2222 and 2224 each have a counterclockwise spiral structure.

In this arrangement, RF currents flow through adjacent portions of each of the coil lines 2221, 2222, 2223, and 2224 in the same direction. Thus, the intensity of magnetic field does not increase in the adjacent portions of each coil line. However, a direction 2231 in which the RF current flows through the first coil line 2221 is opposite to a direction 2233 in which the RF current flows through the third coil line 2223 at a portion between the first region 2200a and the third region 2200c. Also, a direction 2232 in which the RF current flows through the second coil line 2222 is opposite to a direction 2234 in which the RF current flows through the fourth coil line 2224 at a portion between the second region 2200b and the fourth region 2200d. Accordingly, the intensity of magnetic field increases at these portions between opposite regions.

FIG. 63 is a plan view of a plasma source coil according to another embodiment of the present invention.

Referring to FIG. 63, the plasma source coil 2300 of the present embodiment comprises a conductive bushing 2310; from which one coil line 2320 extends so as to form a plurality of circular layers around the conductive bushing 2310. Specifically, the coil line 2320 diverges from the conductive bushing 2310 and extends around the conductive bushing 2310 so as to form a first circular layer 2320a. After making a turn, the coil line 2320 turns back and extends around the first circular layer 2320a so as to form a second circular layer 2320b. After making another turn, the coil line 2320 turns back and extends around the second circular layer 2320b so as to form a third circular layer 2320c. Also, after making yet another turn, the coil line 2320 turns back and extends around the third circular layer 2320c so as to form a fourth circular layer 2320d.

In this arrangement, as indicated by arrows, RF currents flow through adjacent ones of the circular layers 2320a, 2320b, 2320c, and 2320d, in the opposite directions. Thus, the intensity of magnetic field increases between adjacent circular layers.

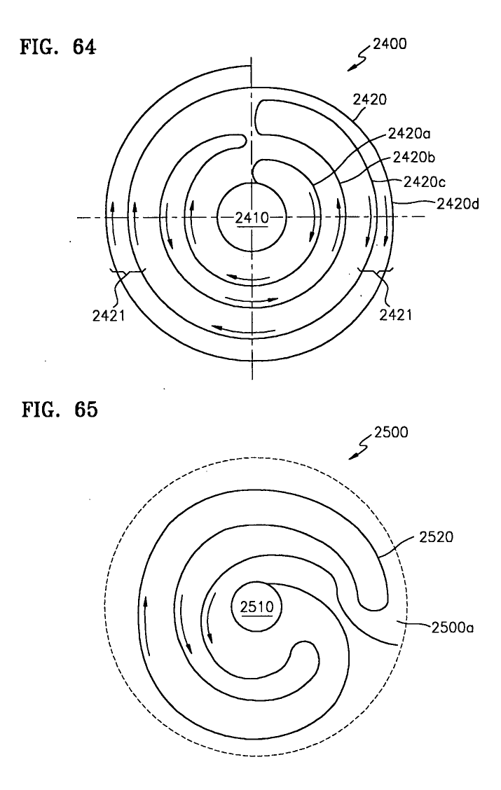

FIG. 64 is a plan view of a plasma source coil according to another embodiment of the present invention.

Referring to FIG. 64, the structure of the plasma source coil 2400 is similar to that of the plasma source coil 2300 of FIG. 63, except that a coil line 2420 makes two or more turn in the same direction once. Specifically, the coil line 2420 diverges from the conductive bushing 2410 and extends around a conductive bushing 2410 so as to form a first circular layer 2420a. After making a turn, the coil line 2420 turns back and extends around the first circular layer 2420a so as to form a second circular layer 2420b. After making another turn, the coil line 2420 turns back and extends around the second circular layer 2420b so as to form a third circular layer 2420c. After making yet another turn, the coil line 2420 does not turn back and keeps extending around the third circular layer 2420c so as to form a fourth circular layer 2420d. As indicated by arrows, RF currents flow through adjacent ones of the circular layers 2420a, 2420b, and 2420c in the opposite directions, whereas RF currents flow through the third circular layer 2420c and the fourth circular layer 2420d in the same direction.

FIG. 65 is a plan view of a plasma source coil according to another embodiment of the present invention.

Referring to FIG. 65, the plasma source coil 2500 of the present embodiment comprises a conductive bushing 2510. A coil line 2520 diverges from the conductive bushing 2510 and extends around the conductive bushing 2510 while making a big turn. After that, the coil line 2520 turns back, extends around the conductive bushing 2510 while making a small turn, and repeats it until the coil line 2520 almost reaches the conductive bushing 2510. Then, the coil line 2520 extends from the vicinity of the conductive bushing 2510 toward a circular boundary line. In the plasma source coil 2500, as indicated by arrows, RF currents flow through adjacent portions of the coil line 2520 in the opposite directions. Thus, the intensity of magnetic field increases at the adjacent portions of the coil lines 2520.

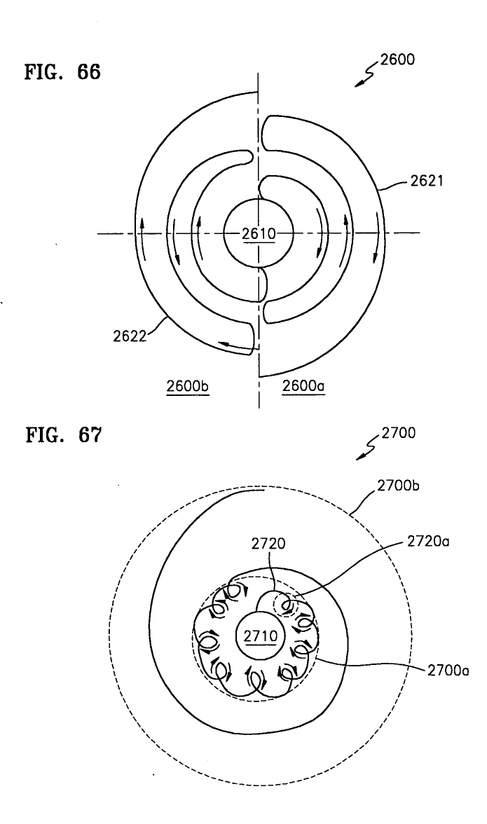

FIG. 66 is a plan view of a plasma source coil according to another embodiment of the present invention.

Referring to FIG. 66, the structure of the plasma source coil 2600 is similar to that of the plasma source coil 2400 of FIG. 64. However, in the plasma source coil 2600, two coil lines, i.e., a first coil line 2621 and a second coil line 2622 diverge from a conductive bushing 2610 symmetrically with respect to the conductive bushing 2610. Also, each of the first coil line 2621 and the second coil line 2622 extends around the conductive bushing 2610, makes a half turn, turns back, and then repeats it. The first coil line 2621 extends in an opposite direction to a direction in which the second coil line 2621 extends. In this plasma source coil 2600, RF currents flow through adjacent portions of the first coil line 2621 or the second coil line 2622 in the opposite directions. Thus, the intensity of magnetic field increases between the adjacent portions of the first coil line 2621 or the second coil line 2622.

FIG. 67 is a plan view of a plasma source coil according to another embodiment of the present invention.

Referring to FIG. 67, the plasma source coil 2700 of the present embodiment comprises a conductive bushing 2710, which is located in the center of a first region 2700a having a relatively small radius and a second region 2700b having a relatively large radius. A coil line 2720 diverges from a conductive bushing 2710, is arranged in a spring shape in the first region 2700a, and then arranged to simply surround the first region 2700a in the second region 2700b. In the first region 2700a of the plasma source coil 2700, a direction in which the RF current flows through a portion 2720a where the coil line 2720 is twisted is opposite to directions in which the RF current flows through adjacent portions where the coil line 2720 is twisted as indicated by arrows. Thus, the intensity of magnetic field increases between adjacent portions where the coil line 2720 is twisted.

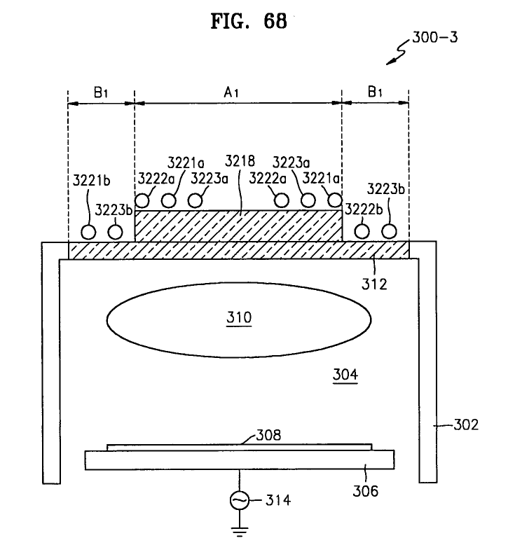

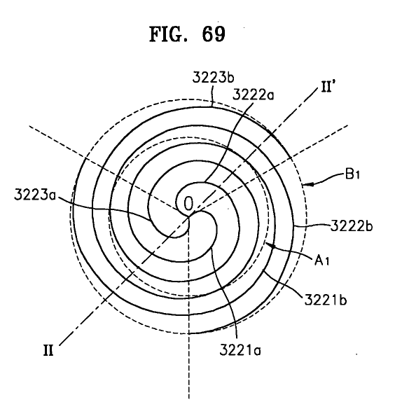

FIG. 68 is a cross-sectional view of a plasma chamber according to another embodiment of the present invention. FIG. 69 shows an example of a plasma source coil of the plasma chamber of FIG. 68. The cross-sectional view of FIG. 68 is taken along line II-II′ of FIG. 69.

Referring to FIGS. 68 and 69, the plasma chamber 300-3 of the present embodiment is similar to the plasma chamber 300 of FIG. 2 with the exception of the plasma source coil. In the plasma chamber 300-3, the plasma source coil for generating plasma is located on an outer surface of a dome 312. The plasma source coil is comprised of a plurality of unit coils, for example, first unit coils 3221a and 3221b, second unit coils 3222a and 3222b, and third unit coils 3223a and 3223b, which diverge from a central point O. In particular, these unit coils are distributed throughout a first region A1, which is located above, and a second region B2, which is located below. More specifically, the first, second, and third unit coils 3221a, 3222a, and 3223a are arranged in a spiral shape around the central point O in the first region A1, which is located farther from the top surface of the dome 312 than the second region B1. For this, the first, second, and third unit coils 3221a, 3222a, and 3223a are arranged on an insulating material layer, for example, a ceramic layer 3218, located on the top surface of the dome 312. In this case, the first, second, and third unit coils 3221a, 3222a, and 3223a are spaced at least the thickness of the ceramic layer 3218 apart from the top surface of the dome 312. The ceramic layer 3218 may be replaced by air according to circumstances. If air replaces the ceramic layer 3218, the plasma chamber 300-3 may further require a support portion for supporting the first, second, and third unit coils 3221a, 3222a, and 3223a.

In the second region B1, which is located closer to the top surface of the dome 312 than the first region A1, the first, second, and third unit coils 3221b, 3222b, and 3223b extend from the first, second, and third unit coils 3221a, 3222a, and 3223a, respectively, and are arranged in a spiral shape. Thus, the second region B1 surrounds the first region A1. As a result, the first region A1 is located to correspond to a central portion of a wafer 308 loaded in the plasma chamber 300-3, and the second region B1 is located to correspond to an edge of the wafer 308. Although not shown in the drawing, the unit coils 3221a, 3221b, 3222a, 3222b, 3223a, and 3223b are connected to an RF power supplier (not shown) to receive RF power from the RF power supplier.

In the plasma chamber 300-3, the first, second, and third unit coils 3221b, 3222b, and 3223b in the second region B1 corresponding to the edge of the wafer 308 are spaced farther from an inner space 304 of the plasma chamber 300-3, while the first, second, and third unit coils 3221a, 3222a, and 3223a in the first region A1 corresponding to the central portion of the wafer 308 are spaced closer to the inner space 304 of the plasma chamber 300-3. Thus, a relatively high density of plasma in the central portion of the wafer 308 can be reduced, while a relatively high density of plasma in the edge of the wafer 308 can be increased. As a result, the density of plasma can be uniform irrespective of positions of the wafer 308.

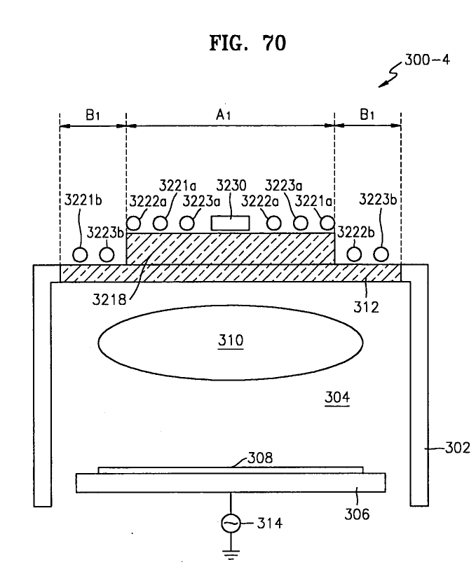

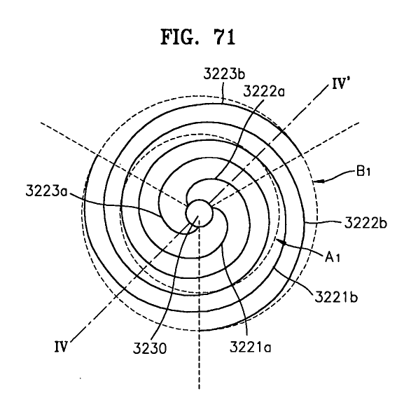

FIG. 70 is a cross-sectional view of a plasma chamber according to another embodiment of the present invention. FIG. 71 shows an example of a plasma source coil of the plasma chamber of FIG. 70. The cross-sectional view of FIG. 70 is taken along line IV-IV′ of FIG. 71. In FIG. 70, the same reference numerals are used to denote the same elements as in FIG. 68.

Referring to FIGS. 70 and 71, the structure of the plasma chamber 3004 is similar to that of the plasma chamber 300-3 of FIG. 68, except that the plasma source coil of FIG. 70 located on a dome 312 further comprises a coil bushing 3230. That is, a coil bushing 3230 having a certain radius is located in the center of a first region A, and a first unit coil 3221a, a second unit coil 3222a, and a third unit coil 3223a diverge from the coil bushing 3230 and are located in a spiral shape around the coil bushing 3230. This coil bushing 3230 is formed of a conductive material and connected to an RF power supplier (not shown) so as to supply RF power to the first, second, and third unit coils 3221a, 3222a, and 3223a. In the plasma chamber 300-4 of the present embodiment, the coil bushing 3230 is located above a central portion of a wafer 308, thus lowering the density of plasma in the center of the wafer 308 more effectively. As a result, the density of plasma can be uniform irrespective of positions of the wafer 308.

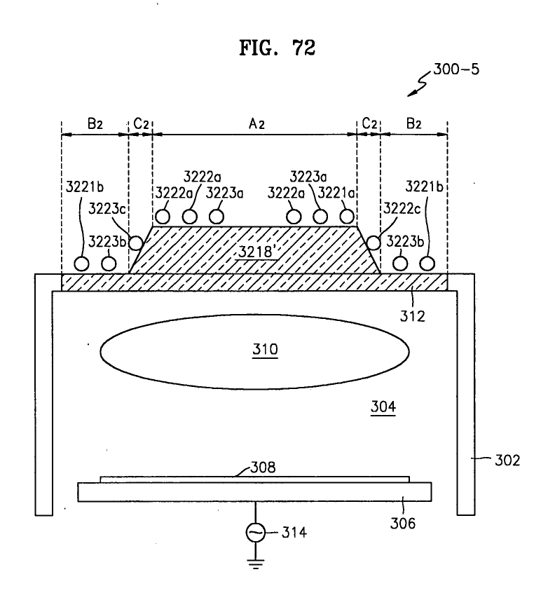

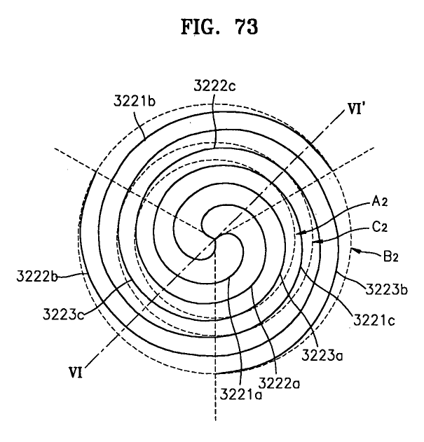

FIG. 72 is a cross-sectional view of a plasma chamber according to another embodiment of the present invention. FIG. 73 shows an example of a plasma source coil of the plasma chamber of FIG. 72. The cross-sectional view of FIG. 72 is taken along line VI-VI′ of FIG. 73. In FIG. 72, the same reference numerals are used to denote the same elements as in FIG. 68.

Referring to FIGS. 72 and 73, in the plasma chamber 300-5 of the present embodiment, the structure of a plasma source coil located on an outer surface of a dome 312 is different from those in other embodiments. That is, the plasma source coil is comprised of a plurality of unit coils, for example, first unit coils 3221a, 3221b, and 3221c, second unit coils 3222a, 3222b, and 3222c, and third unit coils 3223a, 3223b, and 3223c, which diverge from a central point O. In particular, these unit coils are distributed throughout a first region A2, which is located above, a second region B2, which is located below, and a third region C2, which is located between the first region A2 and the second region B2. More specifically, the first, second, and third unit coils 3221a, 3222a, and 3223a are arranged in a spiral shape around the central point O in the first region A1, which is located farther from the top surface of the dome 312 than the second or third region B1 or C1. For this, the first, second, and third unit coils 3221a, 3222a, and 3223a are arranged on an insulating material layer, for example, a ceramic layer 3218′, located on the top surface of the dome 312. The ceramic layer 3218′ has slant lateral surfaces. In this case, the first, second, and third unit coils 3221a, 3222a, and 3223a are spaced at least the thickness of the ceramic layer 3218′ apart from the top surface of the dome 312. The ceramic layer 3218′ may be replaced by air according to circumstances. If air replaces the ceramic layer 3218′, the plasma chamber 300-5 may further require a support portion for supporting the first, second, and third unit coils 3221a, 3222a, and 3223a.

Once the unit coils 3221a, 3222a, and 3223a reach edges of the first region A2, they start extending in a spiral shape along the slant surfaces of the third region C2. That is, the first, second, and third unit coils 3221c, 3222c, and 3223c extend from the first, second, and third unit coils 3221a, 3222a, and 3223a, respectively, and coil the ceramic layer 3218′ along the slant lateral surfaces of the ceramic layer 3218′ until they reach the second region B2.

In the second region B2, which is located closer to the top surface of the dome 312 than the first and third regions A2 and C2, the first, second, and third unit coils 3221b, 3222b, and 3223b extend from the first, second, third unit coils 3221c, 3222c, and 3223c of the third region C2 and are arranged in a spiral shape. Thus, the second region B2 is located to surround the first region A2 and the third region C2. The first region A2 is located to correspond to a central portion of a wafer 308, the second region B2 is located to correspond to an edge of the wafer 308, and the third region C2 is located between the first and second regions A2 and B2. Although not shown in the drawing, the unit coils 3221a, 3221b, 3221c, 3222a, 3222b, 3222c, 3223a, 3223b, and 3223c are connected to an RF power supplier (not shown) to receive RF power from the RF power supplier.

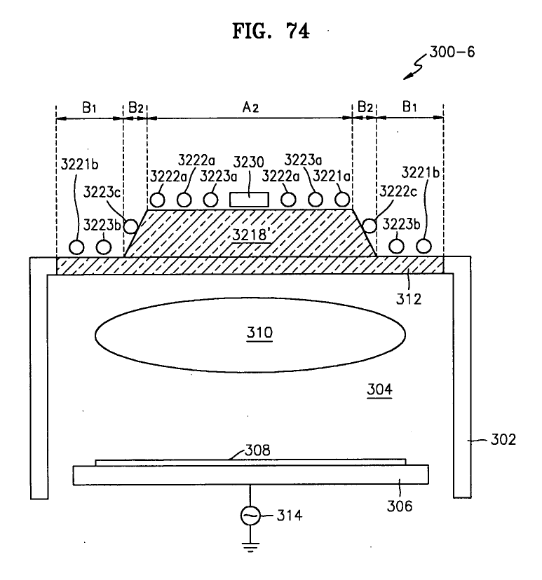

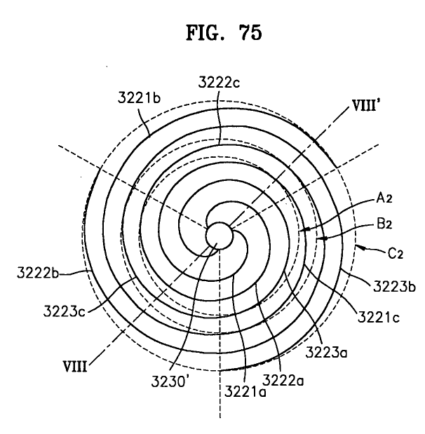

FIG. 74 is a cross-sectional view of a plasma chamber according to another embodiment of the present invention. FIG. 75 shows an example of a plasma source coil of the plasma chamber of FIG. 74. The cross-sectional view of FIG. 74 is taken along line VIII-VIII′ of FIG. 75. In FIG. 74, the same reference numerals are used to denote the same elements as in FIG. 70.

Referring to FIGS. 74 and 75, the structure of the plasma chamber 300-6 is similar to that of the plasma chamber 300-5 of FIG. 72, except that a plasma source coil located on an outer surface of a dome 312 further comprises a coil bushing 3230′. That is, the coil bushing 3230′ having a certain radius is located in the center of a first region A2. A first unit coil 3221a, a second unit coil 3222a, and a third unit coil 3223a diverge from the coil bushing 3230′ and are located in a spiral shape around the coil bushing 3230′. The coil bushing 3230′ is formed of a conductive material and connected to an RF power supplier (not shown) so as to supply RF power to the first, second, and third unit coils 3221a, 3222a, and 3223a. In the plasma chamber 300-6, the coil bushing 3230′ is located above a central portion of a wafer 308, thus lowering the density of plasma in the central portion of the wafer 308 more effectively. As a result, the density of plasma can be uniform irrespective of positions of the wafer 308.

While the present invention has been particularly shown and described with reference to preferred embodiments thereof, it will be understood by those of ordinary skill in the art that various changes in form and details may be made therein without departing from the spirit and scope of the present invention as defined by the following claims.

What is claimed is:

1. A plasma source coil for generating plasma in a predetermined reaction space, the plasma source coil comprising:
m unit coils, each of which has a number n of turns, which extend from a coil bushing having a predetermined radius in the center of the plasma source coil and are arranged in a spiral shape around the coil bushing,
wherein m is an integer more than or equal to 2, and n is a positive real number.

2. The plasma source coil of claim 1, wherein the coil bushing is formed of the same conductive material as the unit coils.

3. The plasma source coil of claim 2, wherein the unit coils and the coil bushing are formed of copper.

4. The plasma source coil of claim 1, wherein the coil bushing has a shape selected from the group consisting of a circle, a circular donut, and polygons, such as a square, a square donut, a hexagon, a hexagonal donut, an octagon, an octagonal donut, and a triangle.

5. The plasma source coil of claim 1, wherein each of the unit coils has a shape selected from the group consisting of a circle, a circular donut, a semicircle, and polygons, such as a square, and a square donut.

6. The plasma source coil of claim 1, wherein each of the unit coils is structured such that as the radial distance from the coil bushing increases, interval between portions of the unit coil in the radial direction decreases.

7. The plasma source coil of claim 6, wherein as radial distance from the coil bushing increases, the sectional area of the unit coil decreases.

8. The plasma source coil of claim 1, wherein each of the unit coils is structured such that as the radial distance from the center of the coil bushing increases, the sectional area of the unit coil decreases.

9. A plasma chamber comprising:
a chamber having outer walls and a dome, a reaction space of the chamber being defined by the outer walls and the dome;
a wafer support located at a lower portion of the chamber, the wafer support for supporting semiconductor wafers;
a plasma source coil located on the dome of the chamber, the plasma source coil for including m unit coils, each of which has a number n of turns, which extend from a coil bushing having a predetermined radius in the center of the plasma source coil and are arranged in a spiral shape around the coil bushing, wherein m is an integer more than or equal to 2, and n is a positive real number;
a support bar located in a certain central region of the coil bushing of the plasma source coil; and
an induction coil connected to the support bar, the induction coil for supplying power to the plasma source coil.

10. The plasma chamber of claim 9, wherein the coil bushing and the support bar each are formed of the same conductive material as the unit coils of the plasma source coil.

11. The plasma chamber of claim 10, wherein the unit coils, the coil bushing, and the support bar are formed of copper.

12. The plasma chamber of claim 9, wherein the coil bushing has a shape selected from the group consisting of a circle, a circular donut, and polygons, such as a square, a square donut, a hexagon, a hexagonal donut, an octagon, an octagonal donut, and a triangle.

13. The plasma chamber of claim 9, wherein each of the unit coils has a shape selected from the group consisting of a circle, a circular donut, a semicircle, and polygons, such as a square and a square donut.

14. The plasma chamber of claim 9, wherein each of the unit coils is structured such that as the radial distance from the coil bushing increases, interval between portions of the unit coil in the radial direction decreases.

15. The plasma chamber of claim 14, wherein as radial distance from the coil bushing increases, the sectional area of the unit coil decreases.

16. The plasma chamber of claim 9, wherein each of the unit coils is structured such that as the radial distance from the center of the coil bushing increases, the sectional area of the unit coil decreases.

17. The plasma chamber of claim 9, wherein the dome is formed of alumina.

18. The plasma chamber of claim 9, wherein the dome comprises:
a lower dome exposed to the reaction space, the lower dome formed of a material having a first dielectric constant; and
an upper dome located on the lower dome, the upper dome formed of a second dielectric constant that is different from the first dielectric constant.

19. A plasma source coil for generating plasma in a predetermined reaction space, the plasma source coil comprising:
a bushing pillar located in a vertical direction, the bushing pillar having a first surface, which is a lower surface, and a second surface, which is an upper surface; and
m unit coils, which diverge from the bushing pillar on the same plane with the second surface of the bushing pillar and are arranged in a spiral shape along the circumference of the second surface of the bushing pillar, wherein when the two or more unit coils reach a certain radius, the unit coils extend on the same plane with the first surface of the bushing pillar while maintaining the certain radius.

20. The plasma source coil of claim 19, further comprising an insulating pillar surrounding the bushing pillar between the first surface and the second surface, the insulating pillar surrounded by the unit coils.

21. The plasma source coil of claim 19, wherein m is an integer more than or equal to 2, each of the unit coils has a number n of turns, and n is a positive real number.

22. A plasma chamber comprising:
a chamber having outer walls and a dome, a reaction space of the chamber being defined by the outer walls and the dome;
a wafer support located at a lower portion of the chamber, the wafer support for supporting semiconductor wafers;
a plasma source coil located on the dome of the chamber, the plasma source coil for comprising a bushing pillar located in a vertical direction, the bushing pillar having a first surface, which is a lower surface, and a second surface, which is an upper surface, and m unit coils, which diverge from the bushing pillar on the same plane with the second surface of the bushing pillar and are arranged in a spiral shape along the circumference of the second surface of the bushing pillar, wherein when the m unit coils reach a certain radius, the unit coils extend on the same plane with the first surface of the bushing pillar while maintaining the certain radius, and
an induction power supplier connected to the bushing pillar of the plasma source coil, the induction power supplier for supplying power to the unit coils.

23. The plasma chamber of claim 22, further comprising an insulating pillar surrounding the bushing pillar between the first surface and the second surface, the insulating pillar surrounded by the unit coils.

24. The plasma chamber of claim 22, wherein m is an integer more than or equal to 2, each of the unit coils has a number n of turns on the same plane with the second surface of the bushing pillar, and n is a positive real number.

25. A plasma source coil for generating plasma in a predetermined reaction space, the plasma source coil comprising:
a coil bushing for receiving power; and
m unit coils, each of which has a number n of turns, which diverge from the coil bushing and are curved in wave shapes around the coil bushing,
wherein m is an integer more than or equal to 2, and n is a positive real number.

26. The plasma source coil of claim 1, wherein the unit coils are arranged in a spiral shape around the coil bushing.

27. A plasma source coil for generating plasma in a predetermined reaction space, the plasma source coil comprising:
a first plasma source region including m first unit coils, which diverge from a coil bushing for receiving power and are arranged in a spiral shape around the coil bushing; and
a second plasma source region including m second unit coils, which extend from the first unit coils of the first plasma source region and are curved in wave shapes to surround the first plasma source region,
wherein m is an integer more than or equal to 2.

28. A plasma source coil for generating plasma in a predetermined reaction space, the plasma source coil comprising:
a bushing pillar located in a vertical direction, the bushing pillar having a first surface, which is a lower surface, and a second surface, which is an upper surface; and
m unit coils, which diverge from the bushing pillar on the same plane with the second surface of the bushing pillar and are curved in wave shapes to surround the bushing pillar, wherein when the m unit coils reach a certain radius, the unit coils extend on the same plane with the first surface of the bushing pillar while maintaining the certain radius.

29. The plasma source coil of claim 28, further comprising an insulating pillar surrounding the bushing pillar between the first surface and the second surface, the insulating pillar surrounded by the unit coils.

30. The plasma source coil of claim 29, wherein m is an integer more than or equal to 2, each of the unit coils has a number n of turns on the same plane with the second surface of the bushing pillar, and n is a positive real number.

31. A plasma source coil comprising:
a chamber having outer walls and a dome, a reaction space of the chamber being defined by the outer walls and the dome;
a wafer support located at a lower portion of the chamber, the wafer support for supporting semiconductor wafers;
a coil bushing and a plasma source coil including m unit coils, which diverge from the coil bushing and are arranged to surround the coil bushing, wherein m is an integer more than or equal to 2; and
an induction power supplier for supplying power to the unit coils via the coil bushing.

32. A plasma chamber comprising:
a chamber having outer walls and a dome, a reaction space of the chamber being defined by the outer walls and the dome;
a wafer support located at a lower portion of the chamber, the wafer support for supporting semiconductor wafers;
a plasma source coil including a first plasma source region including m first unit coils, which diverge from a coil bushing and are arranged in a spiral shape around the coil bushing and a second plasma source region including m second unit coils, which extend from the first unit coils of the first plasma source region and are curved in wave shapes to surround the first plasma source region, wherein m is an integer more than or equal to 2; and
an induction power supplier for supplying power to the unit coils via the coil bushing.

33. A plasma chamber comprising:
a chamber having outer walls and a dome, a reaction space of the chamber being defined by the outer walls and the dome;
a wafer support located at a lower portion of the chamber, the wafer support for supporting semiconductor wafers;
a plasma source coil including a bushing pillar located in a vertical direction, the bushing pillar having a first surface, which is a lower surface, and a second surface, which is an upper surface, and m unit coils, which diverge from the bushing pillar on the same plane with the second surface of the bushing pillar and are curved in wave shapes to surround the bushing pillar, wherein when the m unit coils reach a certain radius, the unit coils extend on the same plane with the first surface of the bushing pillar while maintaining the certain radius; and
an induction power supplier connected to the bushing pillar, the induction power supplier for supplying power to the unit coils.

34. The plasma chamber of claim 33, further comprising an insulating pillar surrounding the bushing pillar between the first surface and the second surface, the insulating pillar surrounded by the unit coils.

35. The plasma chamber of claim 33, wherein m is an integer more than or equal to 2, each of the unit coils has a number n of turns, and n is a positive real number.

36. A plasma source coil for generating plasma in a predetermined reaction space, the plasma source coil comprising:
a conductive bushing located in the center of plasma source coil, the conductive bushing for directly receiving power from a power supplier; and
one or more coil lines, which diverge from the conductive bushing and are arranged around the conductive bushing,
wherein each of the coil lines is located such that currents flow through adjacent portions of the coil line in the opposite directions.

37. The plasma source coil of claim 36, wherein the coil lines diverge from the conductive bushing and are arranged such that clockwise coil lines and counterclockwise coil lines are alternately located.

38. The plasma source coil of claim 37, wherein the conductive bushing has a fan blade shape.

39. The plasma source coil of claim 37, wherein the coil lines include a plurality of coil lines, which diverge from the conductive bushing and are symmetrical with respect to the conductive bushing.

40. The plasma source coil of claim 37, wherein the coil lines include a plurality of coil lines, which are diverge from adjacent portions of the conductive bushing.

41. The plasma source coil of claim 36, further comprising a first ground line and a second ground line, which are spaced a predetermined interval apart from the conductive bushing symmetrically with respect to the conductive bushing.

42. The plasma source coil of claim 41, wherein the coil lines comprise:
a first coil line, which diverges from a first position of the conductive bushing and is located to surround the first ground line in a fan blade shape; and
a second coil line, which diverges from a second position of the conductive bushing, which is opposite to the first position, and is located to surround the second ground line in a fan blade shape.

43. The plasma source coil of claim 41, wherein the coil lines comprise:
a first coil line, which diverges from a first position of the conductive bushing and is located to surround the first ground line in a fan blade shape; and
a second coil line, which diverges from a second position of the conductive bushing, which is adjacent to the first position, and is located to surround the second ground line in a fan blade shape.

44. The plasma source coil of claim 36, further comprising a first ground line, a second ground line, a third ground line, and a fourth ground line, which are spaced a predetermined interval apart from the conductive bushing symmetrically with respect to the conductive bushing.

45. The plasma source coil of claim 44, wherein the coil lines comprise:
a first coil line, which diverges from a first position of the conductive bushing and is located to surround the first ground line in a fan blade shape;
a second coil line, which diverges from a second position of the conductive bushing and is located to surround the second ground line in a fan blade shape;
a third coil line, which diverges from a third position of the conductive bushing and is located to surround the third ground line in a fan blade shape; and
a fourth coil line, which diverges from a fourth position of the conductive bushing and is located to surround the fourth ground line in a fan blade shape.

46. The plasma source coil of claim 44, wherein the coil lines comprise:
a first coil line, which diverges from a first position of the conductive bushing and is located to surround the first ground line in a spiral shape;
a second coil line, which diverges from a second position of the conductive bushing and is located to surround the second ground line in a spiral shape;
a third coil line, which diverges from a third position of the conductive bushing and is located to surround the third ground line in a spiral shape; and
a fourth coil line, which diverges from a fourth position of the conductive bushing and is located to surround the fourth ground line in a spiral shape.

47. The plasma source coil of claim 36, wherein the coil lines are arranged to surround the conductive bushing in a spring shape in a first region having a relatively small radius, and
the coil lines are arranged to surround the first region in a spiral shape in a second region having a relatively large radius.

48. A plasma source coil for generating plasma in a predetermined reaction space, the plasma source coil comprising:
a plurality of conductive bushings spaced a regular interval apart from one another, the conductive bushings for directly receiving power from a power supplier; and
a plurality of coil lines, which diverge from the respective conductive bushings and are arranged to surround the conductive bushings in a spiral shape.

49. The plasma source coil of claim 48, wherein the coil lines surround the conductive bushings in the same direction.

50. The plasma source coil of claim 48, wherein only coil lines facing each other among the coil lines are located to surround in the same direction.

51. A plasma chamber comprising:
a chamber having outer walls and a dome, a reaction space of the chamber being defined by the outer walls and the dome;
a wafer support located at a lower portion of the chamber, the wafer support for supporting semiconductor wafers;
a plasma source coil plasma source coil comprising a conductive bushing located in the center of plasma source coil, the conductive bushing for directly receiving power from a power supplier, and one or more coil lines, which diverge from the conductive bushing and are arranged around the conductive bushing, wherein each of the coil lines is located such that currents flow through adjacent portions of the coil line in the opposite directions; and
an induction power supplier connected to the conductive busing, the induction power supplier for supplying power to the coil lines.

52. A plasma source coil for generating plasma in a predetermined reaction space, the plasma source coil comprising:
a first coil portion comprised of two or more first unit coils, which diverge from a central point of a first region, which corresponds to a center of the reaction space and is spaced a first distance apart from the reaction space, and are located in a spiral shape around the central point of the first region; and
a second coil portion comprised of two or more second unit coils, which extend from the first unit coils and are located in a spiral shape around the first region in a second region, which corresponds to an edge of the reaction space, surrounds the first region, and is spaced a second distance apart from the reaction space,
wherein the second distance is shorter than the first distance.

53. A plasma source coil for generating plasma, the plasma source coil comprising:
a coil bushing located in the center of a first region, which corresponds to a central portion of the reaction space and is spaced a first distance apart from the reaction space;
a first coil portion comprised of two or more first unit coils, which diverge from the coil bushing in the first region and are arranged in a spiral shape around the coil bushing; and
a second coil portion comprised of two ore more second unit coils, which extend from the first unit coils and are arranged in a spiral shape around the first region in a second region, which corresponds to an edge of the reaction space, surrounds the first region, and is spaced a second distance apart from the reaction space,
wherein the second distance is shorter than the first distance.

54. A plasma source coil for generating plasma, the plasma source coil comprising:
a first coil portion comprised of two or more first unit coils, which diverge from a central point of a first region, which corresponds to a central portion of the reaction space and is spaced a first distance from the reaction space, and are arranged in a spiral shape around the central point of the first region;
a second coil portion comprised of two or more second unit coils, which are arranged in a spiral shape around the first region in a second region, which corresponds to an edge of the reaction space and is spaced a second distance apart from the reaction space; and
a third coil portion comprised of two or more third unit coils, which extend from the first unit coils to the second unit coils in a vertical direction in a third region, which is formed of slant lateral surfaces of the plasma source coil between the first region and the second region,
wherein the second distance is shorter than the first distance.

55. A plasma source coil for generating plasma, the plasma source coil comprising:
a coil bushing located in the center of a first region, which corresponds to a central portion of the reaction space and is spaced a first distance apart from the reaction space;
a first coil portion comprised of two or more first unit coils, which diverge from the coil bushing in the first region and are arranged in a spiral shape around the coil bushing;
a second coil portion comprised of two or more second unit coils, which are arranged in a spiral shape around the first region in a second region, which corresponds to an edge of the reaction space and is spaced a second distance apart from the reaction space; and
a third coil portion comprised of two or more third unit coils, which extend from the first unit coils to the second unit coils in a vertical direction in a third region, which is formed of slant lateral surfaces of the plasma source coil between the first region and the second region,
wherein the second distance is shorter than the first distance.

56. A plasma chamber comprising:
a chamber having outer walls and a dome, a reaction space of the chamber being defined by the outer walls and the dome;
a wafer support located at a lower portion of the chamber, the wafer support for supporting semiconductor wafers;
a plasma source coil comprising a first coil portion comprised of two or more first unit coils, which diverge from a central point of a first region, which corresponds to a center of the reaction space and is spaced a first distance apart from the reaction space, and are located in a spiral shape around the central point of the first region, and a second coil portion comprised of two or more second unit coils, which extend from the first unit coils and are located in a spiral shape around the first region in a second region, which corresponds to an edge of the reaction space, surrounds the first region, and is spaced a second distance apart from the reaction space, wherein the second distance is shorter than the first distance; and
an induction power supplier for supplying power to the unit coils via the coil bushing.

57. A plasma chamber comprising:
a chamber having outer walls and a dome, a reaction space of the chamber being defined by the outer walls and the dome;
a wafer support located at a lower portion of the chamber, the wafer support for supporting semiconductor wafers;
a plasma source coil comprised of a coil bushing located in the center of a first region, which corresponds to a central portion of the reaction space and is spaced a first distance apart from the reaction space, a first coil portion comprised of two or more first unit coils, which diverge from the coil bushing in the first region and are arranged in a spiral shape around the coil bushing, and a second coil portion comprised of two ore more second unit coils, which extend from the first unit coils and are arranged in a spiral shape around the first region in a second region, which corresponds to an edge of the reaction space, surrounds the first region, and is spaced a second distance apart from the reaction space, wherein the second distance is shorter than the first distance;
an induction power supplier for supplying power to the unit coils via the coil bushing.

58. A plasma chamber comprising:
a chamber having outer walls and a dome, a reaction space of the chamber being defined by the outer walls and the dome;
a wafer support located at a lower portion of the chamber, the wafer support for supporting semiconductor wafers;
a plasma source coil comprising a first coil portion comprised of two or more first unit coils, which diverge from a central point of a first region, which corresponds to a central portion of the reaction space and is spaced a first distance from the reaction space, and are arranged in a spiral shape around the central point of the first region, a second coil portion comprised of two or more second unit coils, which are arranged in a spiral shape around the first region in a second region, which corresponds to an edge of the reaction space and is spaced a second distance apart from the reaction space, and a third coil portion comprised of two or more third unit coils, which extend from the first unit coils to the second unit coils in a vertical direction in a third region, which is formed of slant lateral surfaces of the plasma source coil between the first region and the second region, wherein the second distance is shorter than the first distance; and
an induction power supplier for supplying power to the unit coils via the coil bushing.

59. A plasma chamber comprising:
a chamber having outer walls and a dome, a reaction space of the chamber being defined by the outer walls and the dome;
a wafer support located at a lower portion of the chamber, the wafer support for supporting semiconductor wafers;
a plasma source coil comprised of a coil bushing located in the center of a first region, which corresponds to a central portion of the reaction space and is spaced a first distance apart from the reaction space, a first coil portion comprised of two or more first unit coils, which diverge from the coil bushing in the first region and are arranged in a spiral shape around the coil bushing, a second coil portion comprised of two or more second unit coils, which are arranged in a spiral shape around the first region in a second region, which corresponds to an edge of the reaction space and is spaced a second distance apart from the reaction space, and a third coil portion comprised of two or more third unit coils, which extend from the first unit coils to the second unit coils in a vertical direction in a third region, which is formed of slant lateral surfaces of the plasma source coil between the first region and the second region, wherein the second distance is shorter than the first distance; and
an induction power supplier for supplying power to the unit coils via the coil bushing.

60. A plasma chamber comprising:
a chamber having outer walls and a dome, a reaction space of the chamber being defined by the outer walls and the dome, wherein the dome has a protrusion toward the reaction space in a first region corresponding to a central portion of the reaction space such that the thickness of the first region is thicker than the thickness of a second region, which surrounds the first region;
a wafer support located at a lower portion of the chamber, the wafer support for supporting semiconductor wafers;
a plasma source coil comprised of a coil bushing located in the first region of the dome and two or more unit coils, which diverge from the coil bushing in the second region of the dome and are located in a spiral shape around the coil bushing; and
an induction power supplier for supplying power to the unit coils via the coil bushing.

61. A plasma chamber comprising:
a chamber having outer walls and a dome, a reaction space of the chamber being defined by the outer walls and the dome, wherein the dome includes a protrusion toward the outside of the dome in an opposite direction of the reaction space in a first region corresponding to a central portion of the reaction space such that the thickness of the first region is thicker than a second region, which surrounds the first region;
a wafer support located at a lower portion of the chamber, the wafer support for supporting semiconductor wafers;
a plasma source coil comprised of a coil bushing located in the first region of the dome and two or more unit coils, which diverge from the coil bushing in the second region of the dome and are arranged in a spiral shape around the coil bushing; and
an induction power supplier for supplying power to the unit coils via the coil bushing.

62. A plasma chamber comprising:
a chamber having outer walls and a dome, a reaction space of the chamber being defined by the outer walls and the dome, wherein the dome includes a protrusion toward the outside of the dome in an opposite direction of the reaction space in a region corresponding to a central portion of the reaction space;
a wafer support located at a lower portion of the chamber, the wafer support for supporting semiconductor wafers;
a coil bushing located in the center of the region of the dome that corresponds to the center of the reaction space;
a plasma source coil comprised of first unit coils, which extend from the coil bushing in a first region surrounding the coil bushing and coil around the protrusion in a vertical direction, and second unit coils, which extend from the first unit coils in a second region surrounding the first region and are arranged on the dome so as to surround the first region in a horizontal direction; and
an induction power supplier for supplying power to the unit coils via the coil bushing.
